(19) United States
(12) Patent Application Publication
(10) Pub. No.: US 2012/0156848 A1
(43) Pub. Date: Jun. 21, 2012

(54) METHOD OF MANUFACTURING NON-VOLATILE MEMORY DEVICE AND CONTACT PLUGS OF SEMICONDUCTOR DEVICE

(76) Inventors: Sang-ryol YANG, Suwon-si (KR); Ki-hyun HWANG, Seongnam-si (KR); Seung-bae PARK, Yongin-si (KR); Jin-gyun KIM, Yongin-si (KR); Woong LEE, Seoul (KR); Jung-geun JEE, Seoul (KR); Ji-hoon CHOI, Seongnam-si (KR)

(21) Appl. No.: 13/239,594

(22) Filed: Sep. 22, 2011

(30) Foreign Application Priority Data
Dec. 17, 2010 (KR) 10-2010-0129999

(51) Int. Cl. H01L 21/336; H01L 21/768

(52) U.S. Cl. 438/287; 438/667; 257/E21.597; 257/E21.409

(57) ABSTRACT

A method of manufacturing a non-volatile memory device includes alternately stacking interlayer sacrificial layers and interlayer insulating layers on a substrate, forming first openings exposing the substrate, forming sidewall insulating layers on sidewalls of the first openings, and forming channel regions on the sidewall insulating layers. The first openings penetrate the interlayer sacrificial layers and the interlayer insulating layers. The sidewall insulating layers have different thicknesses according to distances from the substrate.

### CROSS-REFERENCE TO RELATED APPLICATION

Korean Patent Application No. 10-2010-0129999, filed on Dec. 17, 2010, in the Korean Intellectual Property Office, and entitled: “Method of Manufacturing Non-Volatile Memory Device and Contact Plugs of Semiconductor Device,” is incorporated by reference herein in its entirety.

### BACKGROUND

An electronic product may demand a capability of processing a high capacity of data with a decrease in its size. As such, the integration of a semiconductor memory device used in such an electronic product may be increased.

### SUMMARY

Embodiments may be realized by providing a method of manufacturing a non-volatile memory device that includes alternately stacking interlayer sacrificial layers and interlayer insulating layers on a substrate, forming first openings exposing the substrate, forming sidewall insulating layers on sidewalls of the first openings, and forming channel regions on the sidewall insulating layers. The first openings penetrate the interlayer sacrificial layers and the interlayer insulating layers. The sidewall insulating layers have different thicknesses according to distances from the substrate.

The thicknesses of the sidewall insulating layers may decrease from upper parts of the first openings toward lower parts of the first openings. Forming the sidewall insulating layers may include depositing an insulating material having a step coverage characteristic such that the insulating material is deposited thicker on the upper parts of the first openings than on the lower parts of the first openings. The sidewall insulating layers may be formed above predetermined heights from the substrate.

Prior to forming the channel regions, the sidewall insulating layers formed at lower surfaces of the first openings may be removed. When the sidewall insulating layers formed at the lower surfaces of the first openings are removed, portions of the sidewall insulating layers formed on the sidewalls of the first openings may be simultaneously removed

The method may include, before forming the sidewall insulating layers, forming opening sacrificial layers in the first openings. The opening sacrificial layers may have second heights that are lower than first heights of the first openings. After forming the sidewall insulating layers, opening sacrificial layers may be removed. The sidewall insulating layers may be formed above the second heights.

The method may include, after forming the channel regions, forming second openings between ones of the channel regions, the second openings exposing the substrate and penetrating the interlayer sacrificial layers and the interlayer insulating layers, removing parts of the interlayer sacrificial layers exposed through the second openings to form side openings, the side openings extending from the second openings and exposing parts of the channel regions and the sidewall insulating layers, forming gate dielectric layers in the side openings, and forming gate electrodes on the gate dielectric layers to fill the side openings, each gate electrode being one of a memory cell transistor electrode and a selection transistor electrode. The method may include, before forming the gate dielectric layers, removing parts of the sidewall insulating layers exposed through the side openings. The channel regions may be formed adjacent to one another in a first direction corresponding to an extending direction of the gate electrodes, and the channel regions may be arrayed in zigzag forms.

The method may include providing a cell array region having memory cell transistors arranged therein, a peripheral circuit region having driving circuits arranged therein, and a connection region connecting the cell array region and the peripheral circuit region to each other. The method may include forming contact plugs in wordlines and selection lines to connect the driving circuits to the wordlines and the selection lines that are connected to the gate electrodes arrayed at same heights from the substrate, in the connection region. The formation of the contact plugs may include forming contact holes that penetrate connection region insulating layers, the contact holes being connected to the substrate, forming contact insulating layers on sidewalls of the contact holes, and forming conductive layers on the contact insulating layers to fill the contact holes.

Embodiments may also be realized by providing a method of manufacturing contact plugs of a semiconductor device that includes forming contact holes in an insulating material on conductors, forming sidewall insulating layers on sidewalls of the contact holes, and forming conductive layers on the sidewall insulating layers to fill the contact holes. Each of the contact holes are connected to one of the conductors. The sidewall insulating layers have different thicknesses according to distances from the conductors. The thicknesses of the sidewall insulating layers may decrease from upper parts of the contact holes toward lower parts of the contact holes.

Embodiments may also be realized by providing a method of manufacturing a semiconductor device that includes forming a stacked structure on a substrate, the stacked structure including a plurality of layers, forming first openings in the stacked structure, forming sidewall insulating layers on sidewalls of the first openings, forming at least one layer on the sidewall insulating layers in the first openings. The first openings include upper portions having greater widths than lower portions thereof, and each of the first openings expose one of the plurality of layers or the substrate. The sidewall insulating layers are excluded adjacent to lower surfaces of the first openings such that portions of the sidewalls of the first openings and the lower surfaces of the first openings are exposed, and the sidewall insulating layers have different thicknesses according to distances from the lower surfaces of the first openings.

Forming the sidewall insulating layers may include depositing an insulating layer and removing portions of the insulating layer to form the sidewall insulating layers. Removing portions of the insulating layer may include reducing a thickness of the insulating layer on the sidewalls of the first openings.

Forming the at least one layer on the sidewall insulating layers in the first openings may include forming channel regions directly on the sidewall insulating layers and forming a buried insulating layer directly on the channel regions. The method may further include forming second openings in the stacked structure, the stacked structure including interlayer sacrificial layers and interlayer insulating layers alternately stacked therein, removing the interlayer sacrificial layers through the second openings to form third openings, portions of the sidewall insulating layers being exposed through ones of the third openings and portions of the channel regions being exposed through others of third openings, and removing the portions of the sidewall insulating layers exposed through the ones of the third openings such that other portions of the channel regions are exposed through the ones of the third openings.

The method may include forming gate dielectric layers directly on the portions of the channel regions exposed through the others of the third openings and directly on the other portions of the channel regions exposed through the ones of the third openings, and forming conductive layers in the third openings directly on the gate dielectric layers. The method may include forming conductive layers directly on the portions of the channel regions exposed through the others of the third openings and directly on the other portions of the channel regions exposed through the ones of the third openings.

Embodiments may also be realized by providing a method of manufacturing a non-volatile memory device that includes alternately stacking interlayer sacrificial layers and interlayer insulating layers on a substrate, forming first openings which penetrate the interlayer sacrificial layers and the interlayer insulating layers to be connected to the substrate, forming sidewall insulating layers having different thicknesses according to heights from the substrate on sidewalls of the first openings, forming gate dielectric layers on the sidewall insulating layers, forming channel regions on the gate dielectric regions, forming second openings among the channel regions, removing parts of the interlayer sacrificial layers exposed through the second openings to form side openings which extend from the second openings and expose parts of the gate dielectric layers and the sidewall insulating layers, and forming gate electrodes in the side openings. The second openings penetrate the interlayer sacrificial layers and the interlayer insulating layers to be connected to the substrate.

### BRIEF DESCRIPTION OF THE DRAWINGS

Features will become apparent to those of ordinary skill in the art by describing in detail exemplary embodiments with reference to the attached drawings, in which:

FIG. 1 illustrates an equivalent circuit diagram of a memory cell array of a non-volatile memory device, according to an exemplary embodiment;

FIG. 2 illustrates an equivalent circuit diagram of a memory cell string of a non-volatile memory device, according to another exemplary embodiment;

FIG. 3 illustrates a schematic perspective view of a 3-dimensional (3-D) structure of memory cell strings of a non-volatile memory device, according to an exemplary embodiment;

FIGS. 4A through 4K illustrate cross-sectional views of a method of manufacturing a non-volatile memory device, according to an exemplary embodiment;

FIG. 5 illustrates a schematic perspective view of a 3-D structure of memory cell strings of a non-volatile memory device, according to an exemplary embodiment;

FIGS. 6A through 6H illustrate cross-sectional views depicting a method of manufacturing a non-volatile memory device, according to an exemplary embodiment;

FIG. 7 illustrates a schematic perspective view of a 3-D structure of memory cell strings of a non-volatile memory device, according to an exemplary embodiment;

FIGS. 8A through 8I illustrate cross-sectional views depicting a method of manufacturing a non-volatile memory device, according to an exemplary embodiment;

FIG. 9 illustrates a cross-sectional view of a connection region of a non-volatile memory device, according to an exemplary embodiment;

FIG. 10 illustrates a schematic block diagram of a non-volatile memory device, according to an exemplary embodiment;

FIG. 11 illustrates a schematic block diagram of a memory card, according to an exemplary embodiment; and

FIG. 12 illustrates a block diagram of an electronic system, according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, according to manufacturing technique and/tolerance, modifications of shown shapes may be expected. Therefore, the embodiments of the inventive concept should not be construed as being limited to specific shapes of regions shown in the specification of the inventive concept, for example, should include changes in shapes resulting from manufacturing. Further, the dimensions of layers and regions may be exaggerated for clarity of illustration in the drawing figures. Like reference numerals refer to like elements throughout.

It will also be understood that when a layer or element is referred to as being “on” another layer or element, it can be directly on the other layer or element, or intervening layers or elements may also be present. Further, it will be understood that when a layer or element is referred to as being “under” another layer or element, it can be directly under, and one or more intervening layers or elements may also be present. In addition, it will also be understood that when a layer is referred to as being “between” two layers, it can be the only layer between the two layers, or one or more intervening layers may also be present.

According to an exemplary embodiment, a non-volatile memory device may include at least one of a cell array region, a peripheral circuit region, a sense amplifier region, a decoding circuit region, and a connection region. The cell array region may include a plurality of memory cells, and a plurality of bitlines and a plurality of wordlines that are electrically connected to the memory cells. The peripheral circuit region may include circuits for, e.g., driving the memory cells. The sense amplifier region may include circuits for, e.g., reading information stored in the memory cells. The connection region may be arrayed between the cell array region and the decoding circuit region. A wiring structure may be arrayed and may electrically connect the wordlines to the decoding circuit region.

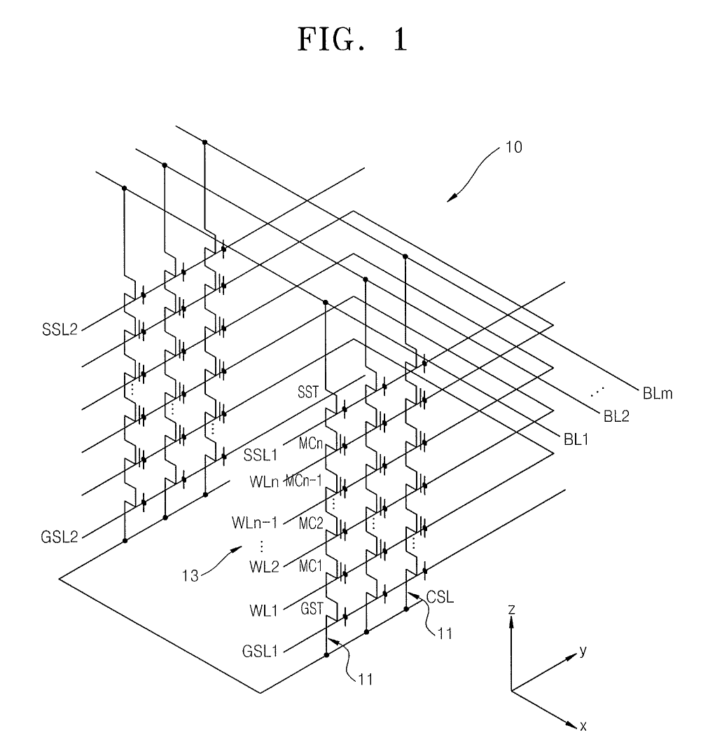

FIG. 1 illustrates an equivalent circuit diagram of a memory cell array of a non-volatile memory device according to an exemplary embodiment. FIG. 1 exemplifies an equivalent circuit diagram of a vertical structure NAND flash memory device having a vertical channel structure. However, embodiments are not limited thereto.

Referring to FIG. 1, a memory cell array 10 may include a plurality of memory cell strings 11. The plurality of memory cell strings 11 may have vertical structures that extend in a first direction, e.g., a z-axis direction, which intersects and/or is perpendicular to extending directions of a main surface of a substrate, e.g., an x-axis direction and a y-axis direction. The memory cell strings may be stacked on the main surface of the substrate 100 in the z-axis direction and may be spaced apart from adjacent memory cell strings in the x-axis and the y-axis directions. The plurality of memory cell strings 11 may constitute a memory cell block 13.

Each of the plurality of memory cell strings 11 may include a plurality of memory cells MC1 through MCn, a string selection transistor (SST), and a ground selection transistor (GST). In each of the plurality of memory cell strings 11, the GST, the plurality of memory cells MC1 through MCn, and the SST are sequentially vertically, e.g., in the z-axis direction, arrayed in series. The plurality of memory cells MC1 through MCn may be configured to store data.

A plurality of bitlines BL1 through BLm may extend in the x-axis direction. The plurality of bitlines BL1 through BLm may be connected to ends of ones of the memory cell strings 11 arrayed in first through mth columns of the memory cell block 13. The plurality of bitlines BL1 through BLm may be connected to drains of the SSTs of the ones of the memory cell strings 11.

A plurality of wordlines WL1 through WLn may be connected to the memory cells MC1 through MCn, respectively, to control the memory cells MC1 through MCn. The number of memory cells MC1 through MCn may be appropriately selected according to a capacity of a semiconductor memory device. The wordlines WL through WLn may extend in a second direction that intersects the extending direction of the memory cell strings 11, e.g., the wordlines WL through WLn may extend in the y-axis direction. The wordlines WL1 through WLn that extend in the y-axis direction may be commonly connected to gates of the memory cells MC1 through MCn, which may be arrayed on the same layers of the plurality of memory cell strings 11. Data may be programmed in, read, and/or erased from the plurality of memory cells MC1 through MCn according to driving of the wordlines WL1 through WL.

Common source lines (CSLs) may be connected to ends of the memory cell strings 11 opposite the plurality of bit lines BL1 through BLm. For example, the CSLs may be connected to sources of the GSTs in the memory cell strings 11.

String selection lines (SSLs) may be connected to ones of the gates of the SSTs. The SST of each of the memory cell strings 11 may be arrayed between the bitlines BL1 through BLm and the memory cells MC1 through MCn. In the memory cell block 13, the SSTs may be configured to control data transmissions between the plurality of bitlines BL1 through BLm and the plurality of memory cells MC1 through MCn through the SSLs that are respectively connected to the gates of the SSTs.

The GSTs may be arrayed between the plurality of memory cells MC1 through MCn and the CSLs. In the memory cell block 13, the GSTs may be configured to control data transmissions between the plurality of memory cells MC1 through MCn and the CSLs through ground selection lines (GSLs) that are respectively connected to gates of the GSTs.

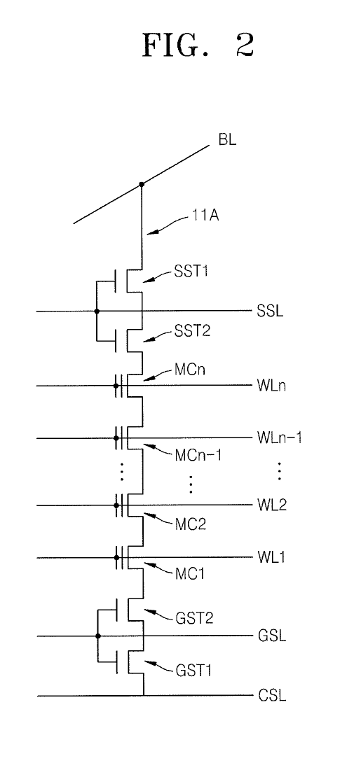

FIG. 2 illustrates an equivalent circuit diagram of a memory cell string of a non-volatile memory device according to another exemplary embodiment. FIG. 2 exemplifies an equivalent circuit diagram of a memory cell string 11A of a vertical structure NAND flash memory device having a vertical channel structure. However, embodiments are not limited thereto. The same reference numerals of FIG. 2 as those of FIG. 1 denote the same elements, and thus their detailed descriptions will be omitted herein.

Each of the SSTs of FIG. 1 may constitute a single transistor. However, in the exemplary embodiment of FIG. 2, instead of the SSTs of FIG. 1, first and second string selection transistors SST1 and SST2 may be arrayed in series between a bitline BL and memory cells MC1 through MCn. Accordingly, a SSL may be commonly connected to gates of the first and second string selection transistors SST1 and SST2. The SSL may correspond to, e.g., a first SSL SSL1 or a second SSL SSL2 of FIG. 1.

Each of the GSTs of FIG. 1 may constitute a single transistor. However, in the exemplary embodiment of FIG. 2, instead of the GSTs of FIG. 1, first and second ground selection transistors GST1 and GST2 may be arrayed in series between a CSL and the memory cells MC1 through CMn. Accordingly, a GSL may be commonly connected to gates of the first and second ground selection transistors GST1 and GST2. The GSL may correspond to, e.g., a first GSL GSL1 or a second GSL GSL2 of FIG. 1.

The bitline BL may correspond to one of the bitlines BL1 through BLm of FIG. 1.

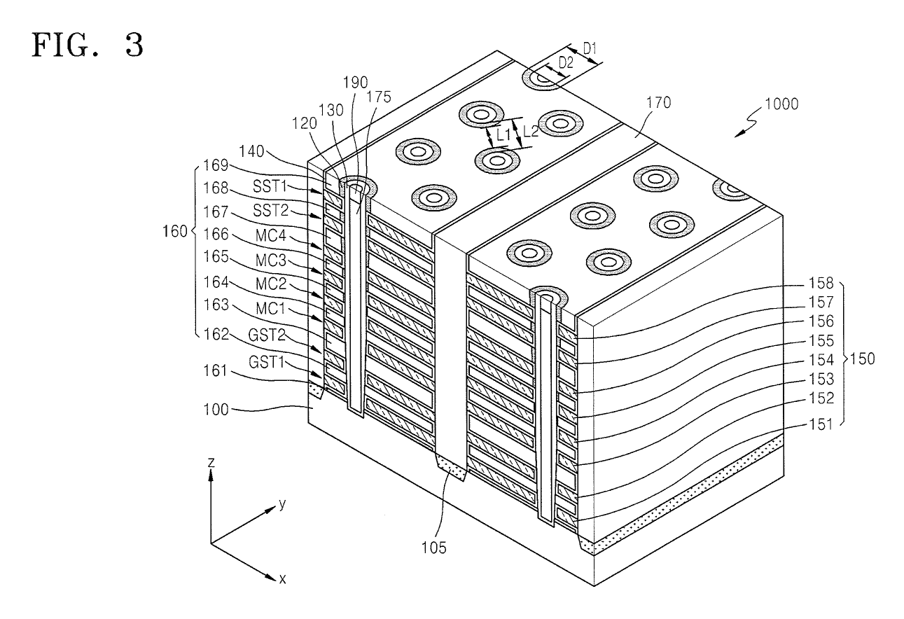

FIG. 3 illustrates a schematic perspective view of a 3-dimensional (3-D) structure of memory cell strings of a non-volatile memory device, according to an exemplary embodiment. Some elements constituting the memory cell strings 11 of FIG. 11 may be omitted in FIG. 3. For example, bitlines of memory cell strings are omitted.

Referring to FIG. 3, a non-volatile memory device 1000 may include channel regions 130 arrayed on a substrate 100 and a plurality of memory cell strings arrayed along sidewalls of the channel regions 130. The plurality of memory cell strings may be arrayed in a y-axis direction along sides of the channel regions 130 arrayed in the y-axis direction. As shown in FIG. 3, the memory cell strings (11 of FIG. 1 or 11A of FIG. 2) may be arrayed to extend from the substrate 100 toward, e.g., the z-axis direction along the sides of the channel regions 130. According to an exemplary embodiment, each of the memory cell strings may include first and second ground selection transistors GST1 and GST2, a plurality of memory cells MC1 through MC4, and first and second string selection transistors SST1 and SST2.

The substrate 100 may have a main surface that extends in the x-axis direction and the y-axis direction. The substrate 100 may include, e.g., a group IV semiconductor, a group III-V compound semiconductor, or a group II-VI oxide semiconductor. For example, the group IV semiconductor may include silicon, germanium, or silicon germanium. The substrate 100 may be provided, e.g., as a bulk wafer or an epitaxial layer.

The channel regions 130 may have pillar shapes that extend in the z-axis direction, e.g., away from the main surface of the substrate 100. The channel regions 130 may be spaced apart from one another in the x-axis direction and the y-axis direction. The channel regions 130 may be arranged in a zigzag pattern along at least one of the x-axis and the y-axis directions. For example, the channel regions 130 that are arrayed adjacent in a row in the y-axis direction may be offset in the x-axis direction. According to an exemplary embodiment, the channel regions 130 may be arranged in two offset columns, e.g., as illustrated in FIG. 3. However, embodiments are not limited thereto, e.g., the channel regions 130 may be arranged in three or more offset columns to be arrayed in zigzag forms.

The channel regions 130 may be formed in annular shapes, e.g., in cylindrical shapes. Lower surfaces of the channel regions 130 may be connected to, e.g., directly in contact with, the substrate 100. The channel regions 130 may be electrically connected to the substrate 100. The channel regions 130 may include a semiconductor material, e.g., a polysilicon or single crystal silicon. The semiconductor material may not be doped with impurities or may be doped with p-type or n-type impurities. As shown in FIG. 3, the adjacent channel regions 130 may be arrayed symmetric to each other, e.g., so that each of insulating regions 170 may be arrayed between the adjacent channel regions 130. However, embodiments are not limited thereto.

Buried insulating layers 175 may be formed in the channel regions 130. The buried insulating layers 175 may be formed on, e.g., directly, on a bottom surface of the channel regions 130. The buried insulating layers 175 may fill, e.g., completely fill, a portion of the channel regions 130. For example, the buried insulating layers 175 may fill channel regions 130 to a height near a height of the first string selection transistor SST1 relative to the substrate 100, e.g., the top surfaces of the buried insulating layers 175 may be adjacent to the first string selection transistor SST1.

Sidewall insulating layers 120 may be formed on portions of the memory cell strings in an area surrounding the channel regions 130. For example, the sidewall insulating layers 120 may contact parts of the channel regions 130 and may be inside the stacked structure of interlayer insulating layers 160 to be arrayed along circumferences of the channel regions 130. The sidewall insulating layers 120 may be formed to be thicker at upper parts of the memory cell strings and to be thinner in a direction toward the substrate 100. For example, the thickest portion of the sidewall insulating layers 120 may be on the first string selection transistor SST1 and the thinnest portion of the sidewall insulating layers 120 may be on the memory cell MC1. As such, thicknesses of the sidewall insulating layers 120 may decrease, e.g., gradually decrease, from a region surrounding the first string selection transistor SST1 to a region surrounding the memory cell MC1. The sidewall insulating layers 120 may not be formed at lower parts of the channel regions 130, i.e., under predetermined heights of the channel regions 130. For example, the sidewall insulating layers 120 may be excluded in a region including the first and second ground selection transistors GST1 and the GST2.

The sidewall insulating layers 120 may include an insulating material, e.g., may be formed of silicon oxide layers. If the sidewall insulating layers 120 are not formed, the channel regions 130 may have first diameters D1 at an upper part of the non-volatile memory device 1000. If the sidewall insulating layers 120 are formed, the channel regions 130 may have second diameters D2 narrower than the first diameters D1 at the upper part. As such, the sidewall insulating layers 120 may have a thickness that is substantially equal to D2 minus D1 at the upper part. Therefore, if the sidewall insulating layers 120 are not formed, the adjacent channel regions 130 may be spaced apart from each other by a first length L1. If the sidewall insulating layers 120 are formed, the adjacent channel regions 130 may be spaced apart by a second length L2 that is larger than the first length L1.

Conductive layers 190 may cover upper surfaces of the buried insulating layers 175 in the channel regions 130, e.g., each conductive layer 190 may be directly on one of the buried insulating layers 175. The conductive layers 190 may be electrically connected to the channel regions 130. The conductive layers 190 and the buried insulating layers 175 may completely fill the channel regions 130. The conductive layers 190 may include, e.g., doped-polysilicon. The conductive layers 190 may operate as drain regions of the first and second string selection transistors SST1 and SST2.

The first string selection transistors SST1 may be arrayed in the x-axis direction and may be commonly connected to bitlines (not shown; refer to FIG. 2) through the conductive layers 190. The bitlines may be formed in line-shaped patterns that extend in the x-axis direction and the bitlines may be electrically connected to the first string selection transistors SST1 through bitline contact plugs (not shown) formed on the conductive layers 190. The first ground selection transistors GST1 may be arrayed in the x-axis direction and may be electrically connected to impurity regions 105 that are adjacent to ones of the first ground selection transistors GST1.

The impurity regions 105 may be formed in the substrate 100. For example, the impurity regions 105 may extend adjacent to the main surface of the substrate 100 in the y-axis direction and may be spaced apart from other impurity regions 105 in the x-axis direction. Each of the impurity regions 105 may be arrayed between the adjacent channel regions 130 in the x-direction. The impurity regions 105 may be formed under the insulating regions 170, e.g., each impurity region 105 may correspond to one of the insulating regions 170. For example, each insulating region 170 may overlap, e.g., completely overlap, one impurity region 105. The impurity regions 105 may be, e.g., source regions, and may form PN junctions with other regions of the substrate 100. The CSLs of FIGS. 1 and 2 may be connected to the impurity regions 105 connection regions (not-shown). The impurity regions 105 may include, e.g., heavily-doped impurity regions (not shown) that are adjacent to the main surface of the substrate 100 and located in the center of the substrate 100 and lightly-doped impurity regions (not shown) that are arrayed at both ends of each of the heavily-doped impurity regions.

Each of the insulating regions 170 may be formed between rows of the channel regions 130. For example, each of the insulating regions 170 may be formed between the adjacent memory cell strings that use the different channel regions 130.

A plurality of gate electrodes 150 (151 through 158) may be arranged along sides of the channel regions 130. Each of the gate electrodes 150 may be spaced apart from one another from the substrate 100 in the z-axis direction. For example, the gate electrode 151 may be spaced apart from the gate electrode 152 along the z-axis direction. The gate electrodes 150 may be commonly connected to the memory cell string that is arrayed adjacent to the gate electrodes 150 in the y-axis direction. The gate electrodes 150 (151 through 158) may be gates of the first and second ground selection transistors GST1 and GST2, the memory cells MC1 through MC4, and the first and second string selection transistors SST1 and SST2, respectively. For example, the gate electrodes 157 and 158 of the first and second string selection transistors SST1 and SST2 may be connected to the SSL (refer to FIG. 1). The gate electrodes 153, 154, 155, and 156 of the memory cells MC1 through MC4 may be connected to the wordlines WL1 through WLn, respectively (refer to FIGS. 1 and 2). The gate electrodes 151 and 152 of the first and second ground selection transistors GST1 and GST2 may be connected to the GSL (refer to FIG. 1). The gate electrodes 150 may include a metal layer, e.g., tungsten (W). Although not shown in FIG. 3, the gate electrodes 150 may further include diffusion barriers (not shown). For example, the diffusion barriers may include at least one of tungsten nitride (WN), tantalum nitride (TaN), and titanium nitride (TiN).

Gate dielectric layers 140 may be arrayed between the channel regions 130 and the gate electrodes 150. Although not shown in FIG. 3, in detail, the gate dielectric layers 140 may include stacked structures. The stacked structures may include, e.g., tunneling insulating layers, charge storage layers, and blocking insulating layers that are sequentially stacked. The stacked structures may be adjacent to the channel regions 130. The gate dielectric layers 140 may surround the gate electrodes 150. For example, the stacked structures of the gate dielectric layers 140 may be arranged adjacent to the channel regions 130 and may extend to surround upper and lower surfaces of the gate electrodes 150.

The tunneling insulating layers may tunnel charges to the charge storage layers using, e.g., a Fowler-Nordhem (F-N) method. The tunneling insulating layers may include, e.g., silicon oxide. The charge storage layers may be charge trap layers or floating gate conductive layers. For example, the charge storage layers may include quantum dots or nanocrystals. The quantum dots or the nanocrystals may be formed of fine particles of a conductor, e.g., fine particles of a metal or a semiconductor. The blocking insulating layers may include, e.g., a high-k dielectric material. The high-k dielectric material may refer to a dielectric material having a higher dielectric constant than an oxide layer.

A plurality of interlayer insulating layers 160 (161 through 169) may be arranged between the gate electrodes 150. Like the gate electrodes 150, the interlayer insulating layers 160 may be spaced apart from one another in the z-axis direction and may extend in the y-axis direction. Each interlayer insulating layer, e.g., one of 161 through 169, may be arranged between adjacent gate electrodes of the gate electrodes 150. For example, interlayer insulating layer 163 may be arranged between gate electrode 152 and gate electrode 153. A depth of the interlayer insulating layers 160 in the z-axis direction may be varied, e.g., interlayer insulating layers 163 and 167 may have a greater depth than others of the interlayer insulating layers. Sides of the interlayer insulating layers 160 may contact the channel regions 130 or the sidewall insulating layers 120. The interlayer insulating layers 160 may include, e.g., silicon oxide and/or silicon nitride.

According to an exemplary embodiment, the number of memory cells MC1 through MC4 may be four, e.g., as illustrated in FIG. 3. However, embodiments are not limited thereto. For example, a larger or smaller number of memory cells may be arrayed according to, e.g., a capacity of the semiconductor memory device 1000. A pair of first and second string selection transistors SST1 and SST2 and a pair of first and second ground selection transistors GST1 and GST2 may be arrayed in each of the memory cell strings.

When the number of first and second string selection transistors SST1 and SST2 and the number of first and second ground selection transistors GST1 and GST2 are each two, lengths of gates of the selection gate electrodes 151, 152, 157, and 158 may be greatly reduced compared to if the number of string selection transistors and the number of ground selection transistors are each one. Therefore, the interlayer insulating layers 160 may be filled with the first and second string selection transistors SST1 and SST2 and the first and second ground selection transistors GST1 and GST2, e.g., with reduced void and/or without voids. The first and second string selection transistors SST1 and SST2 and the first and second ground selection transistors GST1 and GST2 may have substantially the same or similar structures from the memory cells MC1 through MC4. However, embodiments are not limited thereto. For example, like the selection string transistor SST and the ground selection transistor GST of the memory cell string of FIG. 1, one of each may be arrayed. The selection string transistor SST and the ground selection transistor GST may have different structures from the memory cells MC1 through MC4.

In the non-volatile memory device 1000 having the 3-D vertical structure according to an exemplary embodiment, the sidewall insulating layers 120 may be formed to reduce slopes of the channel regions 130. For example, the sidewall insulating layers 120 may be formed to compensate for a sloping of the sidewalls defining the channel regions 130. The channel regions 130 may have high aspect ratios on the substrate 100. The sloped of the sidewalls of the channel regions 130 may be formed during a manufacturing process of the channel regions 130 such that the channel regions 130 may have deviations in diameters at upper and lower parts thereof. The deviations in diameters of the upper and lower parts of the channel regions 130 may cause the sloping of sidewalls defining the channel regions 130. The sidewall insulating layers 120 may reduce the possibility of and/or prevent a length between the adjacent channel regions 130 from being decreased due to, e.g., the sloping of the sidewalls defining the channel regions 130.

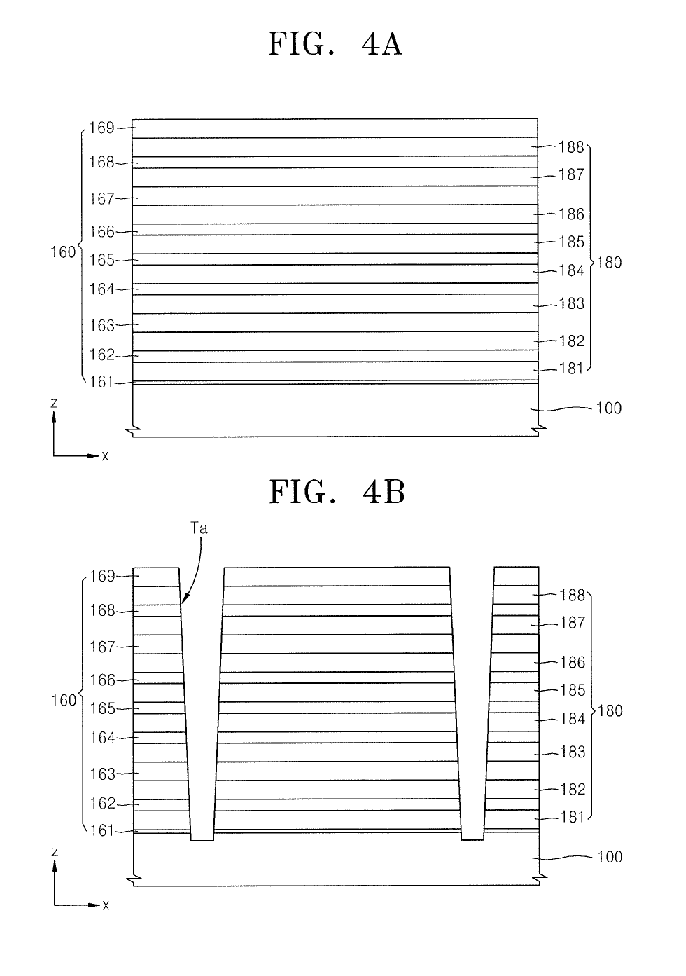

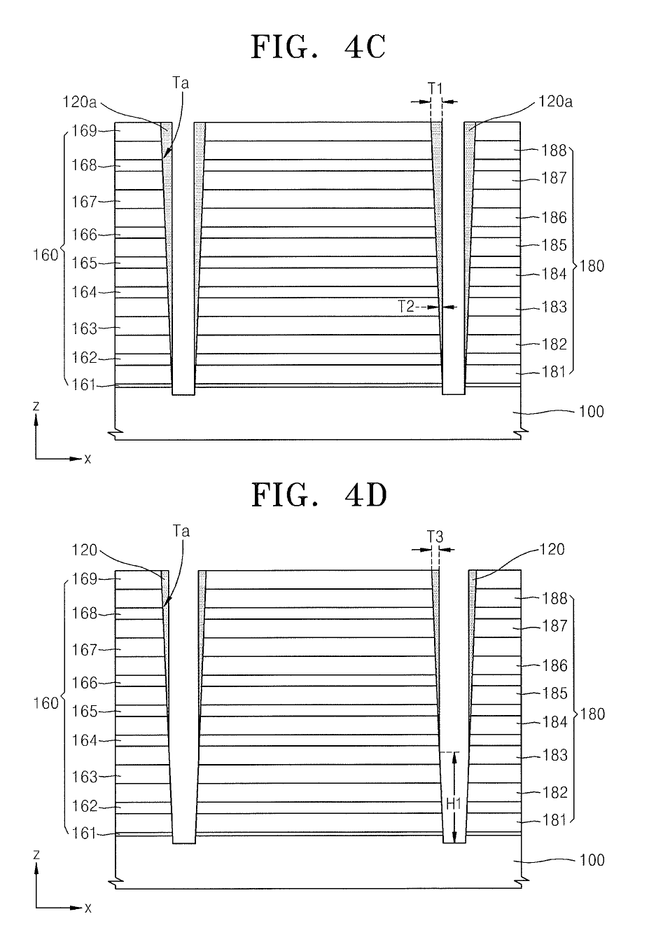

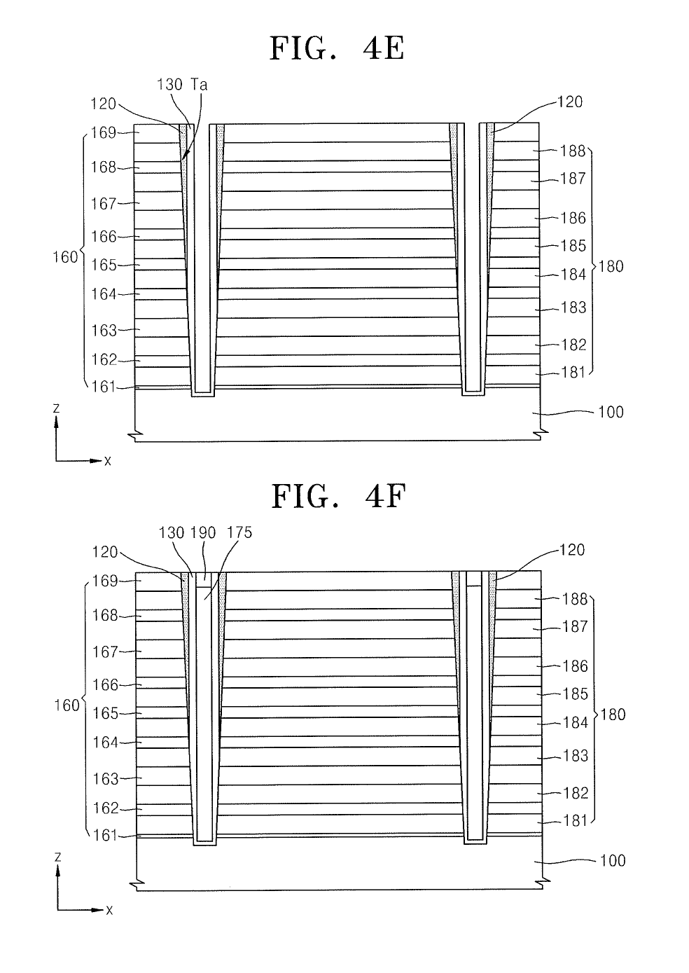

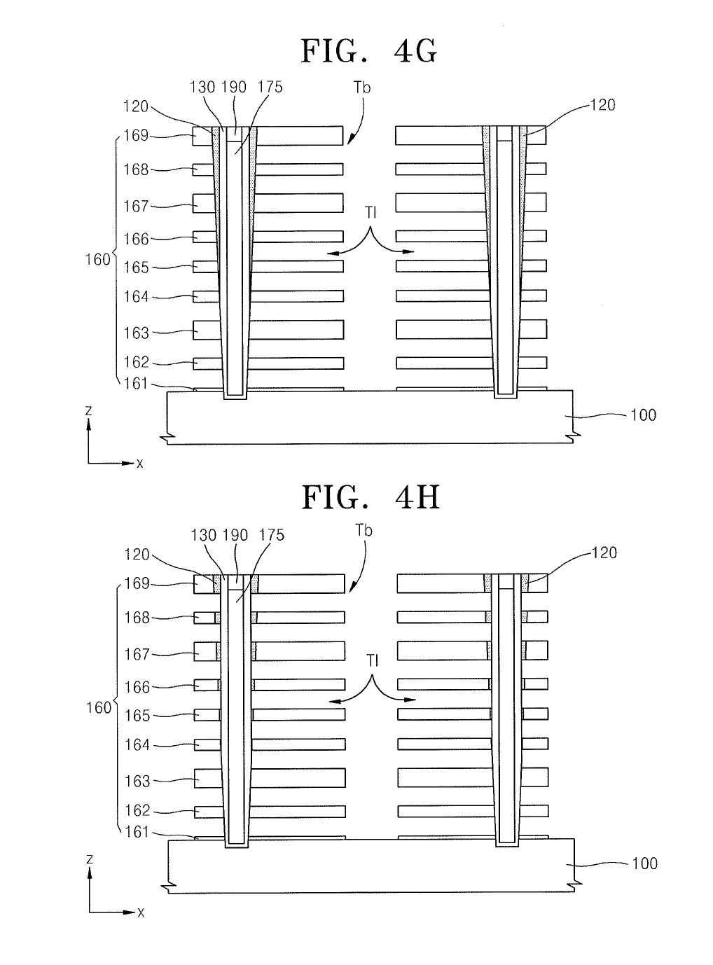

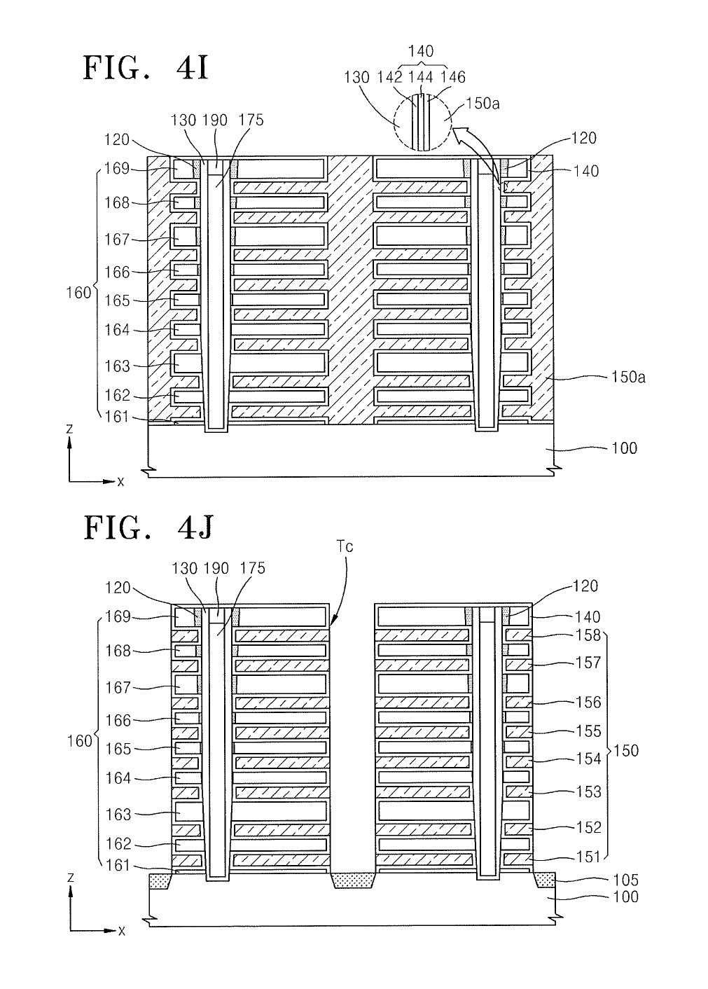

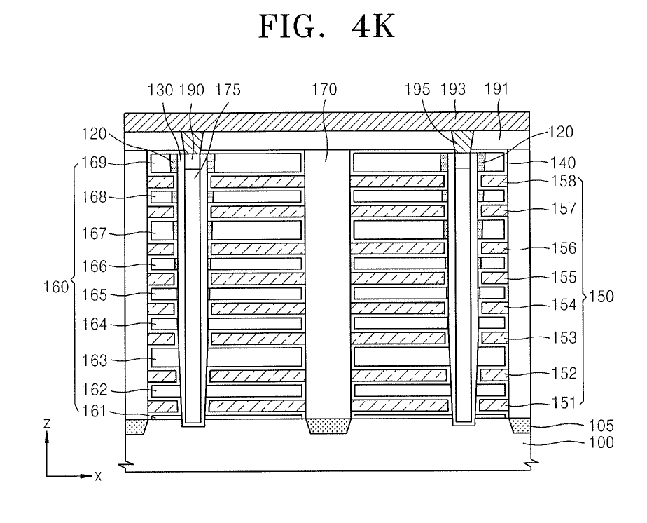

FIGS. 4A through 4K illustrate cross-sectional views of a method of manufacturing the non-volatile memory device 1000 of FIG. 3, according to an exemplary embodiment. The cross-sectional views are taken along the y-axis direction of the perspective view of FIG. 3.

Referring to FIG. 4A, a plurality of interlayer sacrificial layers 180 (181 through 188) and the plurality of interlayer insulating layers 160 (161 through 169) are alternately stacked on the substrate 100 to form a stacked structure. As shown in FIG. 4A, the interlayer sacrificial layers 180 and the interlayer insulating layers 160 are alternately stacked on the substrate 100 starting from the first interlayer insulating layer 161. The first interlayer sacrificial layer 181 may be stacked directly on the first interlayer insulating layer 161. The interlayer insulating layer 169 may form an uppermost surface of the stacked structure. As such, the interlayer insulating layer 169 may have a greatest height with respect to the substrate 100 in the stacked structure. The first interlayer insulating layer 161 may have a smallest height with respect to the substrate 100 in the stacked structure.

The interlayer sacrificial layers 180 may be formed of e.g., a material which is etched by having etch selectivity with respect to the interlayer insulating layers 160. In other words, the interlayer sacrificial layers 180 may be formed of a material that may be etched while minimizing the etching of the interlayer insulating layers 160 in a process of etching the interlayer sacrificial layers 180. The etch selectivity may be quantitatively expressed in a ratio of, e.g., an etching speed of the interlayer sacrificial layers 180 to an etching speed of the interlayer insulating layers 160. For example, the interlayer insulating layers 160 may be, e.g., at least one of silicon oxide layers and silicon nitride layers. The interlayer sacrificial layers 180 may be, e.g., one selected from silicon layers, silicon oxide layers, silicon carbide layers, and silicon nitride layers, which are different from the material for the interlayer insulating layers 160.

According to an exemplary embodiment, thicknesses of the interlayer insulating layers 160 may not be the same as shown in FIG. 4A. For example, the first interlayer insulating layer 161 as the lowermost part of the interlayer insulating layers 160 may be much thinner than the other interlayer insulating layers 160. The thicknesses of the interlayer insulating layers 160 and the interlayer sacrificial layers 180 may be variously modified. Further, the number of layers constituting the interlayer insulating layers 160 and the number of layers constituting the interlayer sacrificial layers 180 may be variously modified.

Referring to FIG. 4B, first openings Ta may be formed to penetrate the stacked structure that includes interlayer insulating layers 160 and the interlayer sacrificial layers 180 alternately stacked therein. The first openings Ta may also penetrate an upper surface of the substrate 100. The first openings Ta may be holes having depths in the z-axis direction. The first openings Ta may be isolation regions that are spaced apart from one another in the x-axis direction and the y-axis direction (refer to FIG. 3).

A process of forming the first openings Ta may include forming predetermined mask patterns, which may define positions of the first openings Ta on the interlayer insulating layers 160 and the interlayer sacrificial layers 180 that are alternately stacked on the substrate 100. The process may include alternately anisotropically etching the interlayer insulating layers 160 and the interlayer sacrificial layers 180 using the predetermined mask patterns as etch masks. As such, the process may include etching different types of layers. The aspect ratios of the first openings Ta may be high. The process may include etching sidewalls of the first openings Ta so that the sidewalls may not be completely vertical to an upper surface of the substrate 100, e.g., the sidewalls of the first openings Ta may be sloped.

For example, a diameter of the first openings Ta may gradually decrease in a direction toward the substrate 100. As a distance from the substrate 100 decreases along the sidewalls of the first openings Ta, i.e., close to the upper surface of the substrate 100, widths of the first openings Ta may be decreased. As such, diameters or widths of the first openings Ta may be greatest at uppermost portions of the first openings Ta and diameters or widths of the first openings Ta may be the smallest at lowermost portions of the first openings Ta. The diameters or widths of the first openings Ta may gradually or abruptly decrease between the uppermost portions toward the lowermost portions.

The first openings Ta may expose parts of the upper surface of the substrate 100 or may expose a portion of the substrate 100 below the upper surface. The first openings Ta may be over-etched in the anisotropic etching, thereby recessing parts of the substrate 100 underneath the first openings Ta to predetermined depths as shown in FIG. 4B.

Referring to FIG. 4C, pre-sidewall insulating layers 120a may be formed on the sidewalls of the first openings Ta. The pre-sidewall insulating layers 120a have first thicknesses T1 at upper parts of the first openings Ta and may be thinner toward the substrate 100. The thickness of the pre-sidewall insulating layers 120a may be formed complimentary with diameters or widths of the first openings Ta. For example, as a diameter of one of the first openings Ta increases, a thickness of the corresponding pre-sidewall insulating layers 120a therein increases. The thicknesses of the pre-sidewall insulating layers 120a in the first openings Ta may gradually decrease as a distance to the substrate 100 decreases.

For example, the pre-sidewall insulating layers 120a may have second thicknesses T2, e.g., at a height at which the third interlayer sacrificial layer 183 is disposed adjacent thereto, that are formed thinner than the first thicknesses T1, e.g., at an uppermost surface of the pre-sidewall insulating layers 120a. The pre-sidewall insulating layers 120a may not be formed at lower surfaces of the first openings Ta, e.g., the pre-sidewall insulating layers 120a may be formed at upper portions of the first openings Ta and may be excluded at lower portions of the first openings Ta. If the pre-sidewall insulating layers are formed at lower portions of the first openings Ta, the pre-sidewall insulating layers 120 may be formed to thicknesses thinner than the first thicknesses T1 at the lower surfaces of the first openings Ta.

The pre-sidewall insulating layers 120a may include, e.g., an insulating material. The pre-sidewall insulating layers 120a may be formed of a material having, e.g., a low step coverage characteristic. In other words, the pre-sidewall insulating layers 120a may be deposited to non-uniform thicknesses in the first openings Ta using a material having a low step coverage characteristic to, e.g., have different thicknesses from entrances of the first openings Ta toward the substrate 100. Also, the pre-sidewall insulating layers 120a may not be formed at lower parts of the first openings Ta. A material for the pre-sidewall insulating layers 120a having an appropriate step coverage may be, e.g., selected according to diameters and aspect ratios of the first openings Ta.

According to an exemplary embodiment, the pre-sidewall insulating layers 120a may be formed to thicknesses of dozens of nanometers on the sidewalls of the first openings Ta. For example, the first thicknesses T1 may be within a range of about 30 nm to about 90 nm. However, embodiments of the range are not limited thereto. For example, the range may be about 40 nm to about 80 nm or about 50 nm to about 70 nm. Without intending to be bound by this theory, if the pre-sidewall insulating layers 120a are formed thicker, it may be difficult to form the channel regions 130 (the process of forming which will be described later). If the pre-sidewall insulating layers 120a are formed thinner, it may be difficult for the pre-sidewall insulating layers 120a to relieve slopes of the channel regions 130.

Referring to FIG. 4D, a process of removing parts of the pre-sidewall insulating layers 120a may be performed, e.g., the process may include reducing thicknesses of the pre-sidewall insulating layers 120a on sidewalls of the first openings Ta. Thereafter, the sidewall insulating layers 120 may be formed from the pre-sidewall insulating layers 120a through the removal and/or thickness reduction process. The sidewall insulating layers 120 may have third thicknesses T3 thinner than the first thicknesses T1 at the entrances of the first openings Ta. The sidewall insulating layers 120 may be excluded, e.g., may not remain, under a predetermined height H1 measured with respect to the substrate 100. For example, the sidewall insulating layers 120 may only be formed above the predetermined height H1 in the first openings Ta. According to an exemplary embodiment, the sidewall insulating layers 120 may be excluded below the third interlayer sacrificial layer 183. If the pre-sidewall insulating layers 120a are formed at the lower surfaces of the first openings Ta, parts of the pre-sidewall insulating layers 120a at the lower surfaces of the first openings Ta may be removed by the removal process to expose the substrate 100.

The removal process may be, e.g., a wet cleaning process. The wet cleaning process may be performed using at least one of ammonia (NH₃), hydrogen peroxide (H₂O₂), and fluorine (F), e.g., a mixed solution of ammonia, hydrogen peroxide, and fluorine. The removal process may be an additional process or may be performed as a kind of cleaning process which is to be performed before forming the channel regions 130, which will be described with reference to FIG. 4E.

Referring to FIG. 4E, the channel regions 130 may be formed to cover, e.g., uniformly cover, sidewalls and lower surfaces of the first openings Ta including the sidewall insulating layers 120. For example, the channel regions 130 may substantially completely cover sidewalls and lower surfaces of the first openings Ta. Each of the channel regions 130 may be formed to a thickness, e.g., a thickness within a range of about 1/50 to about ⅕ of a width of each of the first openings Ta. According to an exemplary embodiment, the thickness of each channel region 130 along the sidewalls and a bottom surface of a corresponding first opening Ta may be uniform. Alternatively, a thickness of the channel regions 130 in the first openings Ta may vary.

The channel regions 130 may be formed using, e.g., atomic layer deposition (ALD) or chemical vapor deposition (CVD). The channel regions 130 may be on, e.g., directly contacting, the substrate 100 at the lower surfaces of the first openings Ta to be electrically connected to the substrate 100. The channel regions 130 may not be substantially sloped due to, e.g., the sidewall insulating layers 120. For example, inner surfaces of the channel regions 130, i.e., the surface facing a center of the first openings Ta, may not be substantially sloped due to the sidewall insulating layers 120. Accordingly, the inner surfaces of the channel regions 130 may define openings that substantially exclude deviations in diameters of the upper and lower parts of the channel regions 130.

Referring to FIG. 4F, the buried insulating layers 175 may be buried into the first openings Ta after forming the channel regions 130. Alternatively, before the buried insulating layers 175 are buried into the first openings Ta, a hydrogen annealing process may be further performed to, e.g., anneal a structure including the channel regions 130 in a gas atmosphere including hydrogen or heavy hydrogen. Parts of crystal defects existing in the channel regions 130 may be cured by the hydrogen annealing process.

A planarization process may be performed to remove unnecessary semiconductor and insulating materials covering the uppermost interlayer insulating layer 169. Upper parts of the buried insulating layers 175 may be removed using an etching process or the like. For example, upper parts of the buried insulating layers 170 in the first openings Ta may be removed. The upper parts that are removed may have been disposed adjacent to the uppermost interlayer insulating layer 169 in the first openings Ta. Accordingly, a height of the buried insulating layers 175 in the first openings Ta with respect to the substrate 100, e.g., a lower surface of the substrate 100, may be reduced to a height similar to a height of a portion of the interlayer insulating layer 169 with respect the substrate 100, e.g., the lower surface of the substrate 100.

Thereafter, a material of which the conductive layers 190 are formed may be deposited on the buried insulating layers 175 having the upper parts thereof removed. The planarization process may be re-performed to form the conductive layers 190.

Referring to FIG. 4G, second openings Tb may be formed to expose the substrate 100. The second openings Tb may extend in the y-axis direction (refer to FIG. 3). According to an exemplary embodiment, the second openings Tb may be formed one-by-one for every two of the channel regions 130 as shown in FIG. 4G. However, embodiments are not limited thereto. For example, relative arrangements of the channel regions 130 and the second openings Tb may vary.

The interlayer insulating layers 160 and the interlayer sacrificial layers 180 (refer to FIG. 4F) may be anisotropically etched using, e.g., a photolithography process to form the second openings Tb. The second openings Tb may correspond to regions in which the insulating regions 170 are to be formed in a subsequent process, and the insulating regions 170 may extend in the y-axis direction via the second openings Tb. The interlayer sacrificial layers 180 that are exposed through the second openings Tb may be removed by, e.g., an etch process. Removal of the interlayer sacrificial layers 180 may form a plurality of side openings T1, e.g., a plurality of open spaces, that are interposed between the interlayer insulating layers 160. Parts of sidewalls of the sidewall insulating layers 120 and the channel regions 130 may be exposed through the side openings T1. For example, in areas where the sidewall insulating layers 120 are excluded, the channel regions 130 may be exposed through the side openings T1. In areas where the sidewall insulating layers 120 are included, the sidewall insulating layers 120 may be exposed through the side openings T1.

Referring to FIG. 4H, the sidewalls of the sidewall insulating layers 120 exposed through the side openings T1 may be removed. The removal of the exposed sidewalls of the sidewall insulating layers 120 may be performed using, e.g., a wet etch process. If the sidewall insulating layers 120 are formed of a material having etch selectivity with respect to the interlayer insulating layers 160 and the channel regions 130, the exposed sidewalls of the sidewall insulating layers 120 may be selectivity removed using the difference in etching selectivity. Alternatively, if the sidewall insulating layers 120 do not have an etching selectivity with respect to the interlayer insulating layers 160 or have a low etching selectivity with respect to the interlayer insulating layers 160, an etch time may be controlled to minimize consumption of the interlayer insulating layers 160 during the removal of the sidewall insulating layers 120. For example, the etch time may be controlled based on and/or due to the relatively thinner thicknesses of the sidewall insulating layers 120 than side thicknesses of the interlayer insulating layers 160.

Referring to FIG. 4I, the gate dielectric layers 140 may be formed to uniformly cover parts of the sidewall insulating layers 120, parts of the channel regions 130, parts of the interlayer insulating layers 160, and parts of the substrate 100 that are exposed by the second openings Tb and the side openings T1. For example, the gate dielectric layers 140 may be directly on parts of the channel regions 130 exposed through the removal of the parts of the sidewall insulating layers 120 and the removal of the interlayer sacrificial layers 180.

The gate dielectric layers 140 may include, e.g., tunneling insulating layers 142, charge storage layers 144, and blocking insulating layers 146 that are sequentially stacked from the channel regions 130. The tunneling insulating layers 142, the charge storage layers 144, and the blocking insulating layers 146 may be formed using, e.g., ALD, CVD, and/or physical vapor deposition (PVD).

After forming the gate dielectric layers 140, the second openings Tb and the side openings T1 may be filled, e.g., substantially completely filled, with a conductive material 150a. Thereby, a material for the gate dielectric layers 140 and the conductive material 150a may be fully filled and uniformly deposited between the adjacent channel regions 130 through the second openings Tb. According to an exemplary embodiment, the sidewall insulating layers 120 may be formed, e.g., in first openings Ta, to secure a length between the adjacent channel regions 130. The sidewall insulating layers 120 may be reduce a slope of the first openings Ta prior to forming the channel regions 130 in the first openings Ta.

Referring to FIG. 4J, parts of the conductive material 150a may be etched to form third openings Tc. The remaining parts of the conductive material 150a, which may be buried into the side openings T1 of FIG. 4H between layers of the interlayer insulating layers 160, form the gate electrodes 150. The third openings Tc may be formed using, e.g., an anisotropic etching process. Parts of the gate dielectric layers 140 formed on the upper surface of the substrate 100 may also be removed using, e.g., the anisotropic etching process. Alternatively, parts of the gate dielectric layers 140 formed on sides of the interlayer insulating layers 160 may be removed together.

Impurities may be injected into the substrate 100 through the third openings Tc to form impurity regions 105. The impurity regions 105 may be disposed between adjacent stacks of interlayer insulating layers 160 and gate electrodes 150.

Referring to FIG. 4K, the insulating regions 170 may be buried in the third openings Tc. The insulating regions 170 may be formed of the same material as that of which the interlayer insulating layers 160 are formed. An insulating material may be deposited on the substrate 100 and in the third openings Tc. Thereafter, the insulating material may be planarized to form the insulating regions 170. Each insulating region 170 may overlap one of the impurity regions 105.

Wiring insulating layers 191 may be formed on the conductive layers 190. Bitline contact plugs 195 may be formed to penetrate the wiring insulating layers 191. The bitline contact plugs 195 may be electrically connected to, e.g., directly contact, the conductive layers 190. The bitline contact plugs 195 may be formed using, e.g., a photolithography process and/or an etching process. Bitlines 193 may be formed on the wiring insulating layers 191 and the insulating regions 170. The bitlines 193 may connect, e.g., electrically connect, the bitline contact plugs 195 that are arrayed in the x-axis direction. The bitlines 193 may be formed in line shapes using, e.g., the photolithography and the etch processes.

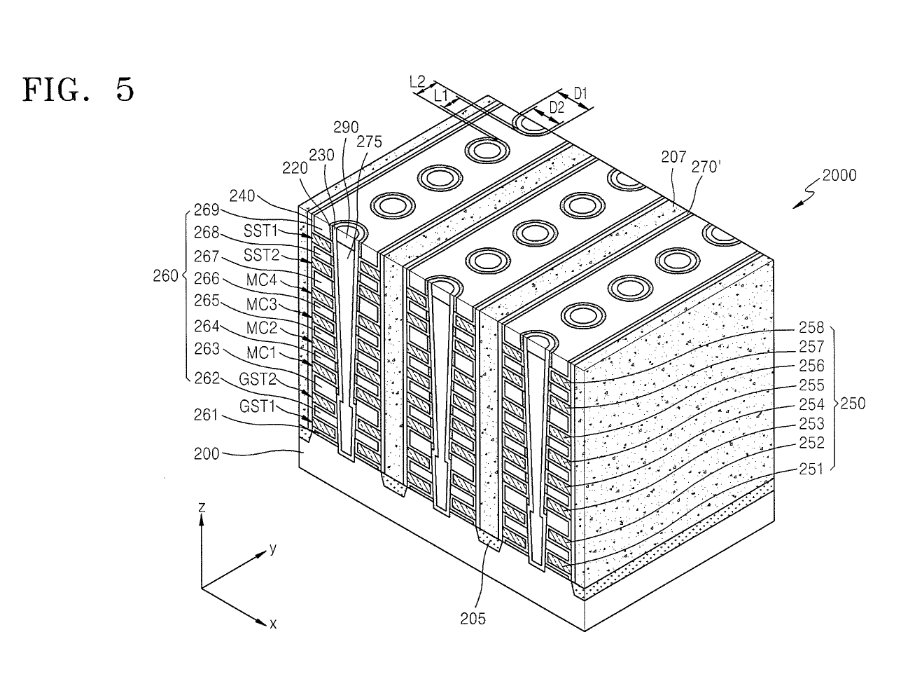

FIG. 5 illustrates a schematic perspective view of a 3-D structure of memory cell strings of a non-volatile memory device 2000, according to another exemplary embodiment. Some elements of the memory cell strings will be omitted in FIG. 5 for ease of explanation. For example, bitlines of the memory cell strings are omitted.

Referring to FIG. 5, the non-volatile memory device 2000 may include channel regions 230 arrayed on a substrate 200 and a plurality of memory cell strings arrayed along sidewalls of the channel regions 230. The plurality of memory cell strings may be arrayed in a y-axis direction along sides of the channel regions 230 that are arrayed in the y-axis direction. As shown in FIG. 5, the memory cell strings (refer to 11 or 11A of FIGS. 1 and 2) may extend from the substrate 200 in a z-axis direction along the sides of the channel regions 230. Each of the memory cell strings may include, e.g., two ground selection transistors, i.e., first and second ground selection transistors GST1 and GST2, a plurality of memory cells MC1 through MC4, and two string selection transistors, i.e., first and second string selection transistors SST1 and SST2.

The substrate 200 may have a main surface that extends in the x-axis direction and the y-axis direction. The memory cell strings may be stacked on the main surface of the substrate 200 in the z-axis direction and spaced apart from adjacent memory cell strings in the x-axis and the y-axis directions. The substrate 200 may include a semiconductor material, e.g., a group IV semiconductor, a group III-V compound semiconductor, or a group II-VI oxide semiconductor.

The channel regions 230 may have pillar shapes to extend in the z-axis direction on the substrate 200. The channel regions 230 may be spaced apart from one another in the x-axis direction and the y-axis direction. According to an exemplary embodiment, the channel regions 230 may be arrayed in rows in the y-axis direction without being offset in the x-axis direction. Lower surfaces of the channel regions 230 may directly contact the substrate 200 so that the channel regions 230 may be electrically connected to the substrate 200. The channel regions 230 may include a semiconductor material, e.g., a polysilicon or a single crystal silicon. Buried insulating layers 275 may be formed in the channel regions 230

Sidewall insulating layers 220 may contact parts of the channel regions 230 inside interlayer insulating layers 260. The sidewall insulating layers 220 may be arranged along outer circumferences of the channel regions 230. According to an exemplary embodiment, the sidewall insulating layers 220 may be formed to uniform thicknesses on upper and lower parts of the channel regions 230 along the memory cell strings. The sidewall insulating layers 220 may not be formed under the lower parts of the channel regions 230, i.e., under predetermined heights. The sidewall insulating layers 220 may include an insulating material, e.g., may be formed of silicon oxide.

If the sidewall insulating layers 220 are excluded, e.g., not formed, the channel regions 230 located in an upper part of the non-volatile memory device 2000 may have first diameters D1. If the sidewalls insulating layers 220 are formed, the channel regions 230 may have second diameters D2 narrower than the first diameters D1. Therefore, if the sidewall insulating layers 220 are not formed, the adjacent channel regions 230 keep a length L1 therebetween. However, if the sidewall insulating layers 220 are formed, the adjacent channel regions 230 may keep a second length L2 longer than the first length L1 therebetween.

Conductive layers 290 may be formed to cover upper surfaces of the buried insulating layers 275. The conductive layers 290 may be electrically connected to the channel regions 230. The conductive layers 290 may include, e.g., doped-polysilicon. The conductive layers 290 may operate as drain regions of the first and second string selection transistors SST1 and SST2.

The first string selection transistors SST1 arrayed in the x-axis direction may be commonly connected to the bitlines (refer to FIG. 2) through the conductive layers 290. The first ground selection transistors GST1 arrayed in the x-axis direction may be electrically connected to impurity regions 205 that are adjacent to the first ground selection transistors GST1.

The impurity regions 205 may be adjacent to the main surface of the substrate 200, may extend in the y-axis direction, and may be spaced apart from adjacent impurity regions 205 in the x-axis direction. The impurity regions 205 may be arrayed one-by-one between two of the channel regions 230 in the x-axis direction.

In the non-volatile memory device 2000 of the current embodiment, CSLs 207 may be arrayed to extend in the z-axis direction on the impurity regions 205. The CSLs 207 may come into contact, e.g., ohmic contacts, with the impurity regions 205. The CSLs 207 may provide source regions to, e.g., the first and second ground selection transistors GST1 and GST2 of the memory cell strings arrayed on the sides of the two channel regions 230 that are adjacent to each other in the x-axis direction. The CSLs 207 may extend in the y-axis direction along, e.g., overlapping, the impurity regions 205. The CSLs 207 may include a conductive material. For example, the CSLs 207 may include at least one metal material selected from Tungsten (W), aluminum (Al), and copper (Cu).

Although not shown in FIG. 5, silicide layers may be interposed between the impurity regions 205 and the CSLs 207. The silicide layers may lower contact resistances between the impurity regions 205 and the CSLs 207. The silicide layers may include metal silicide layers, e.g., cobalt silicide layers.

Spacer insulating regions 270′ may be formed on both sides of each of the CSLs 207. The spacer insulating regions 170′ may overlap the impurity regions 205.

If the impurity regions 205 have an opposite conductive type from the substrate 200, the impurity regions 205 may be source regions of the first and second ground selection transistors GST1 and GST2. If the impurity regions 205 have the same conductive type as the substrate 200, the CSLs 207 may operate as pocket P well contact electrodes for, e.g., erasing operations respectively performed in memory cell blocks. In this case, a high voltage may be applied to the substrate 200 through the pocket P well contact electrodes to erase data from all memory cells of a corresponding memory cell block of the substrate 200.

A plurality of gate electrodes 250 (251 through 258) may be arranged spaced apart from one another from the substrate 200 in the z-axis direction along the sides of the channel regions 230. The gate electrodes 250 may be gates of the first and second ground selection transistors GST1 and GST2, the plurality of memory cells MC1 through MC4, and the first and second string selection transistors SST1 and SST2. The gate electrodes 250 may be commonly connected to the memory cell strings that are arrayed in the y-axis direction and adjacent to the gate electrodes 250.

For example, the gate electrodes 257 and 258 of the first and second string selection transistors SST1 and SST2 may be connected to SSLs (refer to FIG. 1). The gate electrodes 253, 254, 255, and 256 of the memory cells MC1 through MC4 may be connected to wordlines (WL1 through WLn; refer to FIGS. 1 and 2). The gate electrodes 251 and 252 of the first and second ground selection transistors GST1 and GST2 may be connected to GSLs (refer to FIG. 1). The gate electrodes 250 may include metal layers, e.g., W. The gate electrodes 250 may further include diffusion barriers (not shown).

Gate dielectric layers 240 may be arrayed between the channel regions 230 and the gate electrodes 250. Although not shown in FIG. 5 in detail, the gate dielectric layers 240 may include, e.g., tunneling insulating layers, charge storage layers, and blocking insulating layers that may be sequentially stacked from the channel regions 230.

A plurality of interlayer insulating layers 260 (261 through 269) may be arrayed among the gate electrodes 250, e.g., between the gate electrodes 250. Like the gate electrodes 250, the interlayer insulating layers 260 may be spaced apart from one another in the z-axis direction and extend in the y-axis direction. Sides of the interlayer insulating layers 260 may contact the channel regions 230 or sidewall insulating layers 220. The interlayer insulating layers 260 may include, e.g., silicon oxide or silicon nitride.

Four memory cells MC1 through MC4, a pair of first and second string selection transistors SST1 and SST2, and a pair of ground selection transistors GST1 and GST2 may be stacked in each memory string cell on the substrate 200. SSTs and GSTs may have different structures from the memory cells MC1 through MC4.

According to an exemplary embodiment, in the non-volatile memory device 2000 having the 3D vertical structure, the sidewall insulating layers 220 may be formed to reduce slopes of the channel regions 230 and deviations in diameters of upper and lower parts of the channel regions 230 caused by the slopes. The possibility of decreasing a distance between adjacent channel regions 230 may be reduced and/or prevented due to the sidewall insulating layers 220.

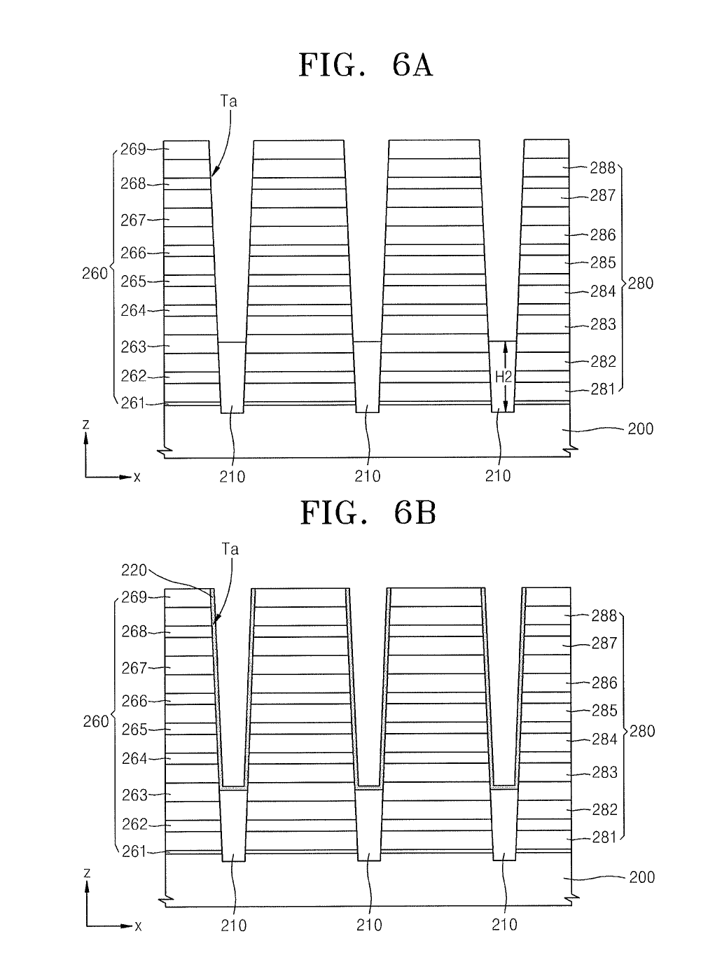

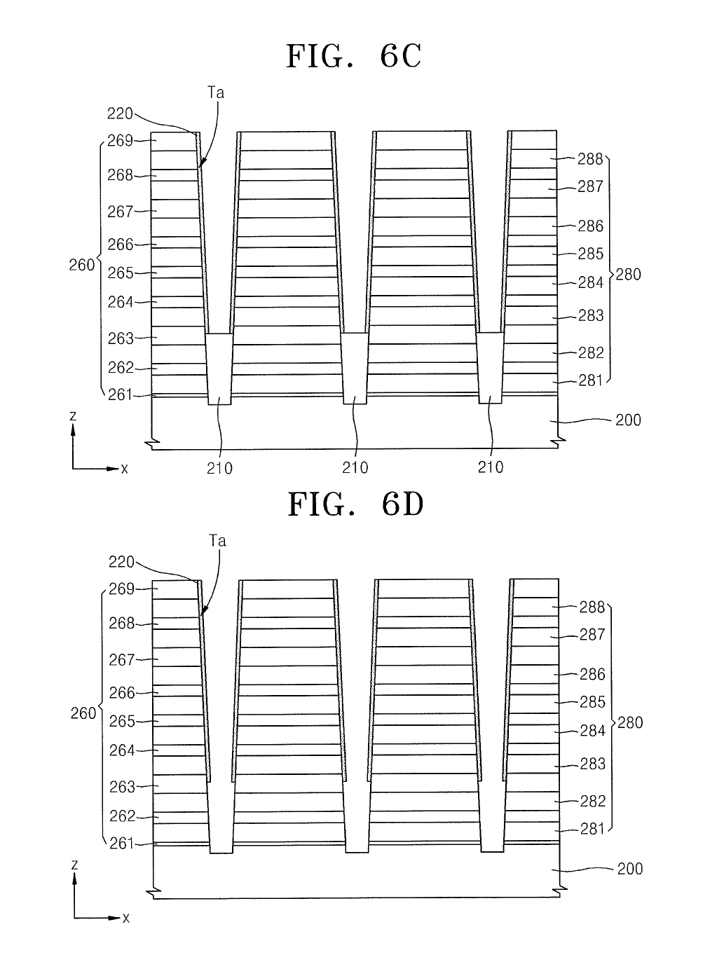

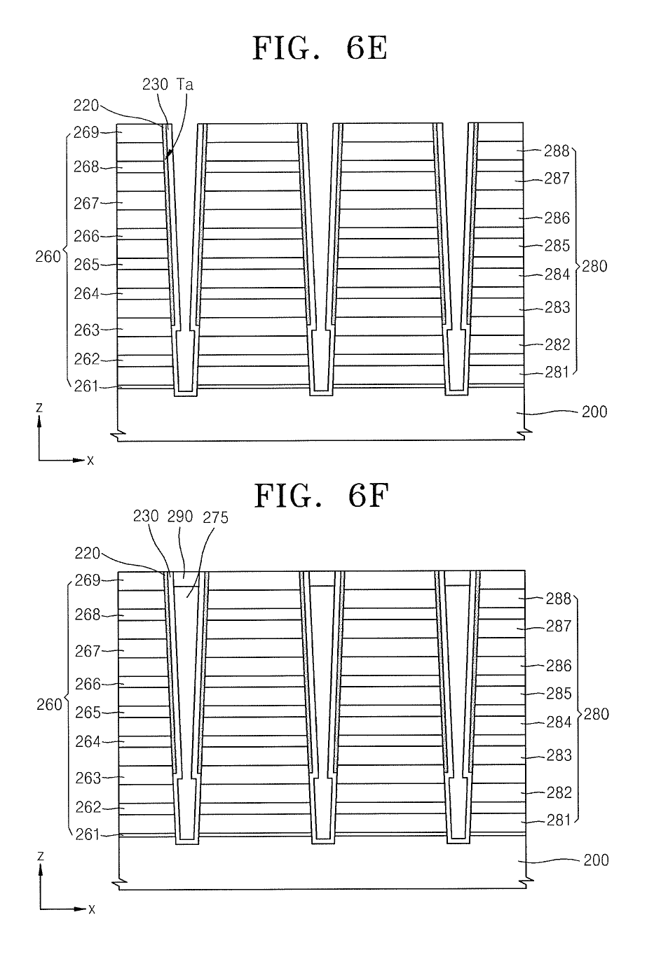

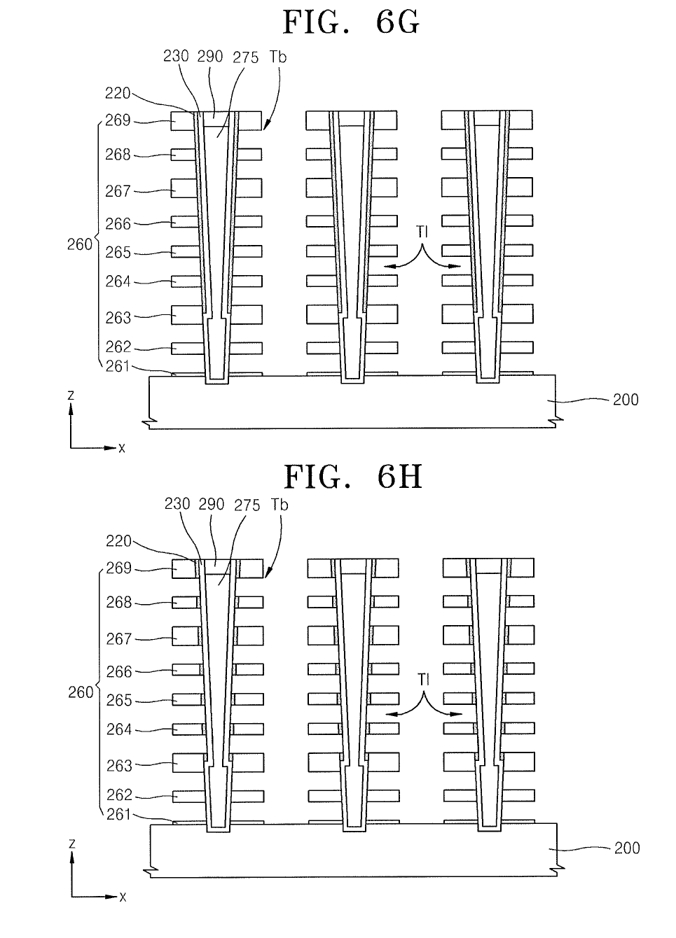

FIGS. 6A through 6H illustrate cross-sectional views of a method of manufacturing the non-volatile memory device 2000 of FIG. 5, according to an exemplary embodiment. Here, the cross-sectional views are taken along the y-axis direction of the perspective view of FIG. 5.

Referring to FIG. 6A as described above with reference to FIGS. 4A and 4B, first openings Ta may be formed in a stacked structure including the interlayer insulating layers 260 and the interlayer sacrificial layers 250 alternately stacked therein.

Opening sacrificial layers 210 may be formed to predetermined heights H2 in the first openings Ta. The opening sacrificial layers 210 may be disposed at lower parts of the first openings Ta, e.g., directly on the substrate 200. The opening sacrificial layers 210 may extend to the predetermined height H2 in the first openings Ta, e.g., to a height below the interlayer sacrificial layer 280 that will define the memory cell MC1 in a subsequent process. The opening sacrificial layers 210 may be formed of, e.g., a material having an etching selectivity with respect to the sidewall insulating layers 220 that will be formed in a subsequent process. The opening sacrificial layers 210 may be at least one of, e.g., silicon layers, silicon oxide layers, silicon carbide layers, and silicon nitride layers. The opening sacrificial layers 210 may be selectively grown from parts of the substrate 200 that are exposed through the first openings Ta or may be deposited on the parts of the substrate 200 using, e.g., a CVD process or an ALD process.

Referring to FIG. 6B, the sidewall insulating layers 220 may be formed on the opening sacrificial layers 210. The sidewall insulating layers 220 may cover, e.g., completely cover, upper surfaces of the opening sacrificial layers 210 and the exposed sidewalls of the first openings Ta. Differently from the previous embodiment, the sidewall insulating layers 220 may be formed to uniform thicknesses. The sidewall insulating layers 220 may be formed to uniform thicknesses on lower surfaces of the first openings Ta. The sidewall insulating layers 220 may include, e.g., an insulating material. The sidewall insulating layers 220 may be formed to dozens of nanometers, e.g., to thicknesses within a range of about 2 nm and 10 nm. Without intending to be bound by this theory, if the sidewall insulating layers 220 are formed thicker, it may be difficult to form the channel regions 230 in the subsequent process. If the sidewall insulating layers 220 are formed thinner, it may be difficult for the sidewall insulating layers 220 to relieve the slopes of the channel regions 230.

Referring to FIG. 6C, a process of removing the sidewall insulating layers 220 formed on parts of upper surfaces of the opening sacrificial layers 210 may be performed. The removing process may be performed using, e.g., an anisotropic etch process. Although not shown in FIG. 6C, when the removal process is performed, parts of lower parts of the sidewall insulating layers 220 may be removed and a thickness of the sidewall insulating layers 220 on the sidewalls of the first openings Ta may be reduced, e.g., made thinner.

Referring to FIG. 6D, a process of removing the opening sacrificial layers 210 may be performed. The removing process may be performed by performing, e.g., a wet etch process using an etchant having etch selectivity with respect to the opening sacrificial layers 210. Although not shown in FIG. 6D, when the removal process is performed, parts of the interlayer insulating layers 260 and/or the interlayer sacrificial layers 280 located around the opening sacrificial layers 210 may also be etched, thereby widening lower parts of the first openings Ta in which the opening sacrificial layers 210 had been formed.

Referring to FIG. 6E, the channel regions 230 may be formed to uniformly cover inner walls and lower surfaces of the first openings Ta. The channel regions 230 may be continuous layers that cover the sidewall insulating layers 220 and the lower parts of the first openings Ta from which the opening sacrificial layers 210 had been removed. Each of the channel regions 230 may be formed to a uniform thickness, e.g., to a thickness in a range of about 1/50 and about ⅕ of a width of each of the first openings Ta. The channel regions 230 may be formed using, e.g., an ALD process or a CVD process. The channel regions 230 may directly contact the substrate 200 at the lower surfaces of the first openings Ta and may be electrically connected to the substrate 200

Referring to FIG. 6F, the buried insulating layers 275 may be buried into the first openings Ta having the channel regions 230 formed therein. A planarization process may be performed to remove unnecessary semiconductor and insulating materials covering the uppermost interlayer insulating layers 269. Parts of upper parts of the buried insulating layers 275 may be removed using, e.g., an etch process or the like, from the first openings Ta. Thereafter, a material for the conductive layers 290 may be deposited in the space of the first openings Ta in which parts of the buried insulating layers 275 had been removed. Another planarization process may be performed to form the conductive layers 290 in the first openings Ta.

Referring to FIG. 6G, the second openings Tb may be formed to expose the substrate 200. The second openings Tb may extend in the y-axis direction (refer to FIG. 5). According to an exemplary embodiment, the second openings Tb may be formed one-by-one for every two of the channel regions 230 as shown in FIG. 6G; however, embodiments are not limited thereto. For example, relative arrangements of the channel regions 230 and the second openings Tb may vary.

The interlayer insulating layers 260 and the interlayer sacrificial layers 280 (refer to FIG. 6F) may be anisotropically etched using, e.g., a photolithography process, to form the second openings Tb. The second openings Tb may correspond to regions in which the CSLs 207 will be formed in a subsequent process. The second openings Tb may extend through the stacked structure in the z-axis direction extend in the y-axis direction between a plurality of the channel regions 230. Parts of the interlayer sacrificial layers 280 exposed through the second openings Tb may be removed using an etch process, thereby forming the plurality of side openings T1 between the interlayer insulating layers 260. Parts of sidewalls of the sidewall insulating layers 220 and the channel regions 230 may be exposed through the side openings T1.

Referring to FIG. 6G, the parts of the sidewall insulating layers 220 exposed through the side openings T1 may be removed. The removal of the exposed parts of the sidewall insulating layers 220 may be performed using, e.g., a wet etch process. If the sidewall insulating layers 220 are formed of a material having an etching selectivity with respect to the interlayer insulating layers 260 and the channel regions 230, the exposed parts of the sidewall insulating layers 220 may be removed using the etching selectivity. Alternatively, if the sidewall insulating layers 220 do not have an etching selectivity with respect to the interlayer insulating layers 260 or have a low etching selectivity with respect to the interlayer insulating layers 260, an etch time may be controlled to minimize consumption of the interlayer insulating layers 260 during the removal of the sidewall insulating layers 220. For example, the etch time may be controlled based on and/or due to relatively thinner thicknesses of the sidewall insulating layers 220 than side thicknesses of the interlayer insulating layers 260.

The similar processes as those of the method of manufacturing the non-volatile memory device 1000 of the previous embodiment described with reference to FIGS. 4I through 4K may be performed to complete the non-volatile memory device 2000 of FIG. 5. For example, in the process described above with reference to FIG. 4K, the spacer insulating regions 270′ may be formed on sidewalls of the third openings Tc and a conductive material for the CSLs 207 may be deposited to form the CSLs 207. An insulating material may be buried into the third openings Tc and an anisotropic etching process may be performed to form the spacer insulating regions 270′. An etch process, such as a deposition process and/or an etch-back process of a conductive material, may be added to form the CSLs 207.

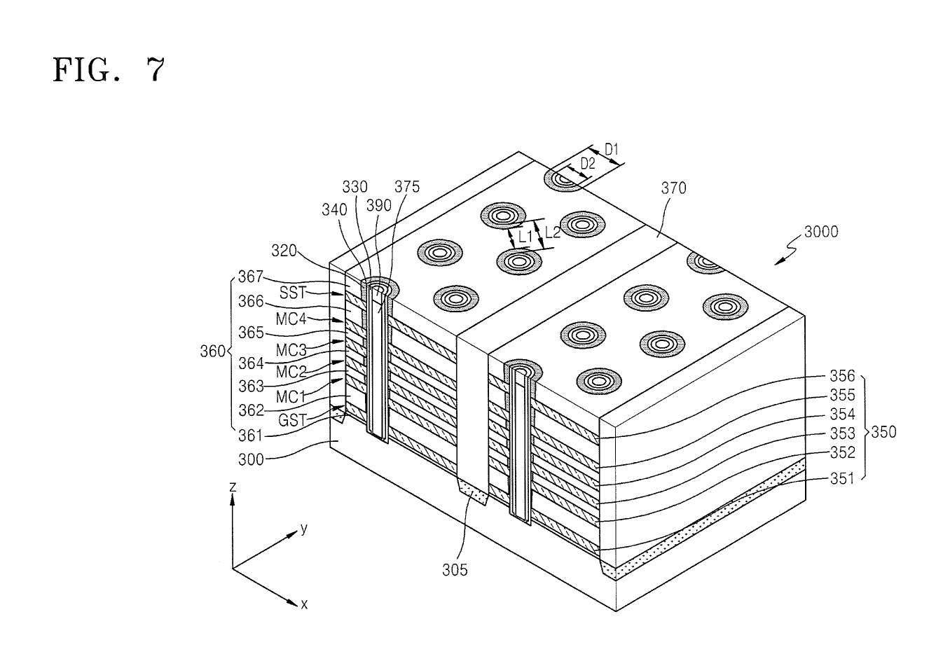

FIG. 7 illustrates a schematic perspective view of a 3-D structure of memory cell strings of a non-volatile memory device 3000, according to another exemplary embodiment. Some elements of the memory cell strings may be omitted in FIG. 7 for ease of exemplary. For example, bitlines of the memory cell strings are omitted.

Referring to FIG. 7, the non-volatile memory device 3000 may include channel regions 330 arrayed on a substrate 300 and a plurality of memory cell strings arrayed along sidewalls of the channel regions 330. The plurality of memory cell strings may be arranged in a y-axis direction along sides of the channel regions 330 that are arrayed in the y-axis direction. As shown in FIG. 7, the memory cell strings (11 or 11A; refer to FIGS. 1 and 2) may extend from the substrate 300 in a z-axis direction along the sides of the channel regions 330. Each of the memory cell strings (11 or 11A) may include, e.g., at least one GST, a plurality of memory cells MC1 through MC4, and at least one SST.

The substrate 300 may have a main surface that extends in an x-axis direction and the y-axis direction. The substrate 300 may include a group IV semiconductor, a group III-V compound semiconductor, or a group II-VI oxide semiconductor. For example, the group IV semiconductor may include silicon, germanium, or silicon germanium.

The channel regions 330 may be arrayed to have pillar shapes and may extend in the z-axis direction on the substrate 300. The channel regions 330 may be spaced apart from one another in the x-axis direction and the y-axis direction and arranged in a zigzag pattern in the y-axis direction. For example, the channel regions 330 arrayed in the y-direction may be offset in the x-direction. The channel regions 300 may be offset in two columns; however, embodiments are not limited thereto. The channel regions 330 may be offset in three or more columns to be arranged in zigzag patterns. The channel regions 330 may be formed in annular shapes. The channel regions 330 may directly contact the substrate 300 and thus may be electrically connected to the substrate 300. The channel regions 330 may include a semiconductor material such as polysilicon or single crystal silicon. The buried insulating layers 375 may be formed in the channel regions 330. As shown in FIG. 7, the channel regions 330 may be repeatedly arrayed so that each of insulating regions 370 may be arranged between the adjacent channel regions 330. However, embodiments are not limited thereto.

Sidewall insulating layers 320 may contact parts of the channel regions 330 inside interlayer insulating layers 360 to be arrayed along circumferences of the channel regions 330. The sidewall insulating layers 320 may be formed to have the greatest thickness at upper parts of the memory cell strings and a smallest thickness toward the substrate 300. The sidewall insulating layers 320 may not be formed at lower parts of the channel regions 330, i.e., under a predetermined height. The sidewall insulating layers 320 may include an insulating material, e.g., may be formed of silicon oxide layers. If the sidewall insulating layers 320 are not formed, the channel regions 330 at an upper part of the non-volatile memory device 3000 may have first diameters D1. If the sidewall insulating layers 320 are formed, the channel regions 330 may have second diameters D2 narrower than the first diameters D1. Therefore, if the sidewall insulating layers 320 are not formed, the adjacent channel regions 330 may keep a first length L1. If the sidewall insulating layers 320 are formed, the adjacent regions 330 may keep a second length L2 longer than the first length L1.

Conductive layers 390 may be formed to cover upper surfaces of the buried insulating layers 375 and to be electrically connected to the channel regions 330. The conductive layers 390 may include, e.g., doped-polysilicon. The conductive layers 390 may operate as, e.g., drain regions of SSTs.

The SSTs arrayed in the x-direction may be commonly connected to bitlines (BL; refer to FIG. 2) through the conductive layers 390. The bitlines (not shown) may be formed in, e.g., line-shaped patterns that extend in the x-axis direction and are electrically connected to one another through contact plugs (not shown) formed on the conductive layers 390. GSTs arrayed in the x-direction may be electrically connected to respective impurity regions 305 that are adjacent to each of the GSTs.

The impurity regions 305 may be adjacent to the main surface of the substrate 300 to extend in the y-axis direction and to be spaced apart from one another in the x-axis direction. According to an exemplary embodiment, the impurity regions 305 may be arranged one-by-one for every two of the channel regions 330 in the x-axis direction. However, embodiments are not limited thereto. The impurity regions 305 may be source regions and may form PN junctions with other regions of the substrate 300. The CSLs of FIGS. 1 and 2 may be connected to the impurity regions 305 (not-shown).

Each of the insulating regions 370 may be formed between the adjacent channel regions 330. In other words, each of the insulating regions 370 may be formed between the adjacent memory cell strings that use the different channel regions 330.

A plurality of gate electrodes 350 (351 through 356) may be spaced apart from one another from the substrate 300 in the z-axis direction, e.g., along the sides of the channel regions 330. The gate electrodes 350 may be gates of the GSTs, the plurality of memory cells MC1 through MC4, and the SSTs. The gate electrodes 350 may be commonly connected to the adjacent memory cell strings arrayed in the y-axis direction. The gate electrodes 356 of the SSTs may be connected to SSLs (refer to FIG. 1). The gate electrodes 352, 353, 354, and 355 of the memory cells MC1 through MC4 may be connected to wordlines (WL1 through WLn; refer to FIGS. 1 and 2). The gate electrodes 351 of the GSTs may be connected to GSLs (refer to FIG. 1). The gate electrodes 350 may include metal layers, e.g., W. The gate electrodes 350 may further include diffusion barriers (not shown).

Gate dielectric layers 340 may be arrayed between the channel regions 330 and the gate electrodes 350. Although not shown in FIG. 7, the gate dielectric layers 340 may include tunneling insulating layers, charge storage layers, and blocking insulating layers, which may be sequentially stacked from the channel regions 330.

A plurality of interlayer insulating layers 360 (361 through 367) may be arrayed among the gate electrodes 350. Like the gate electrodes 350, the interlayer insulating layers 360 may be spaced apart from one another in the z-axis direction and extend in the y-axis direction. Sides of the interlayer insulating layers 360 may contact parts of the channel regions 330 or the sidewall insulating layers 320. The interlayer insulating layers 360 may include, e.g., silicon oxide or silicon nitride.

In the non-volatile memory device 3000 having the 3D vertical structure according to the current embodiment, the sidewall insulating layers 320 may be formed to reduce slopes of the channel regions 330. For example, the channel regions 330 may have deviations in diameters at upper and lower parts of the channel regions 330 caused by the slopes. By forming the sidewall insulating layers 320, the possibility of decreasing lengths between the adjacent channel regions 330 may be reduced and/or prevented.

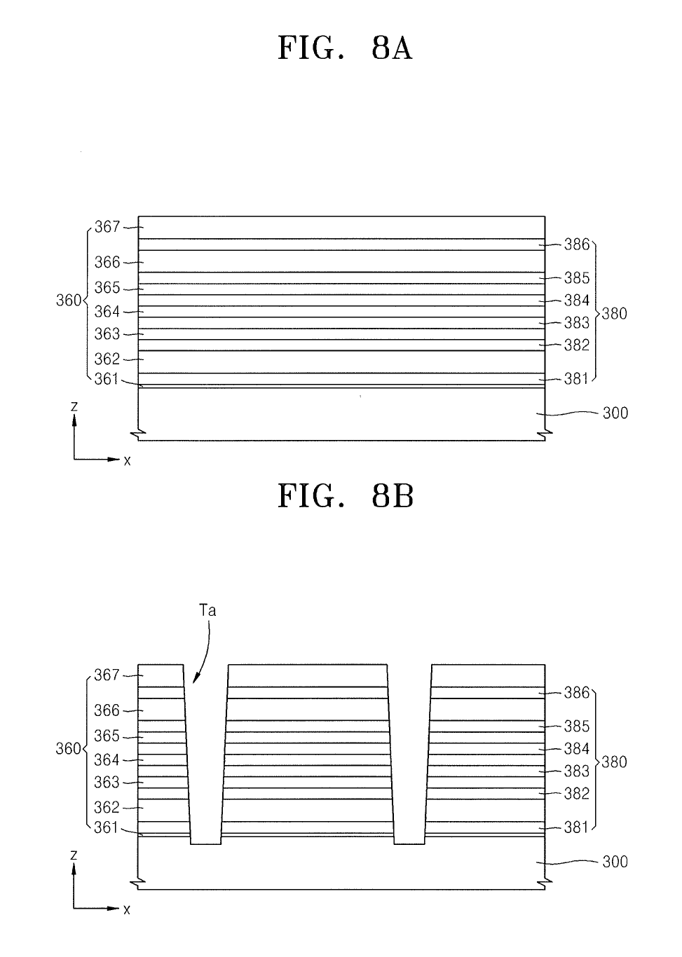

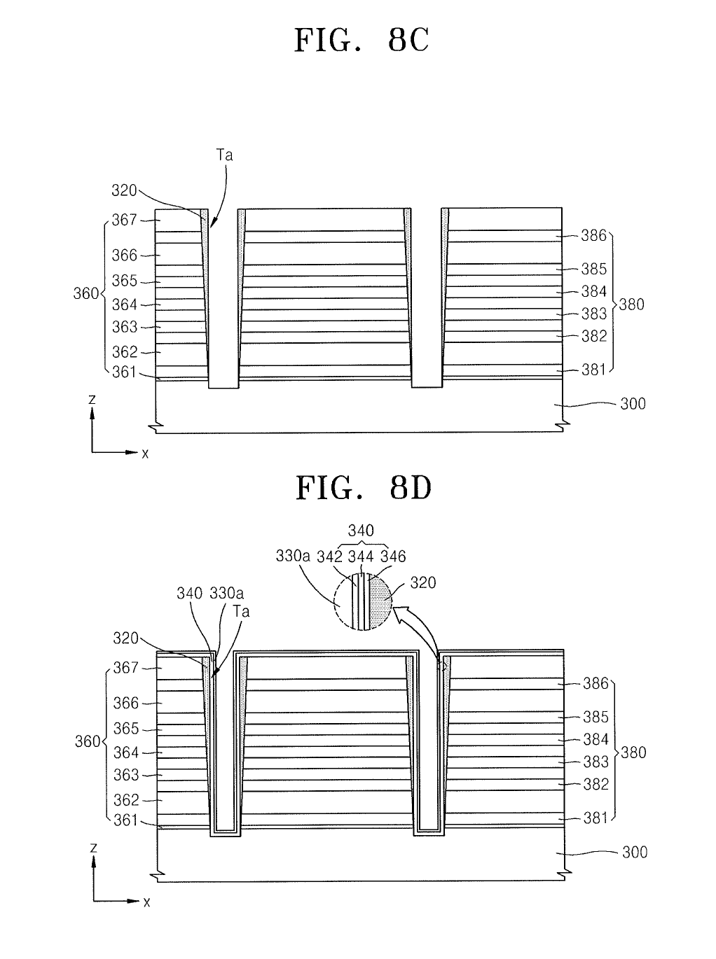

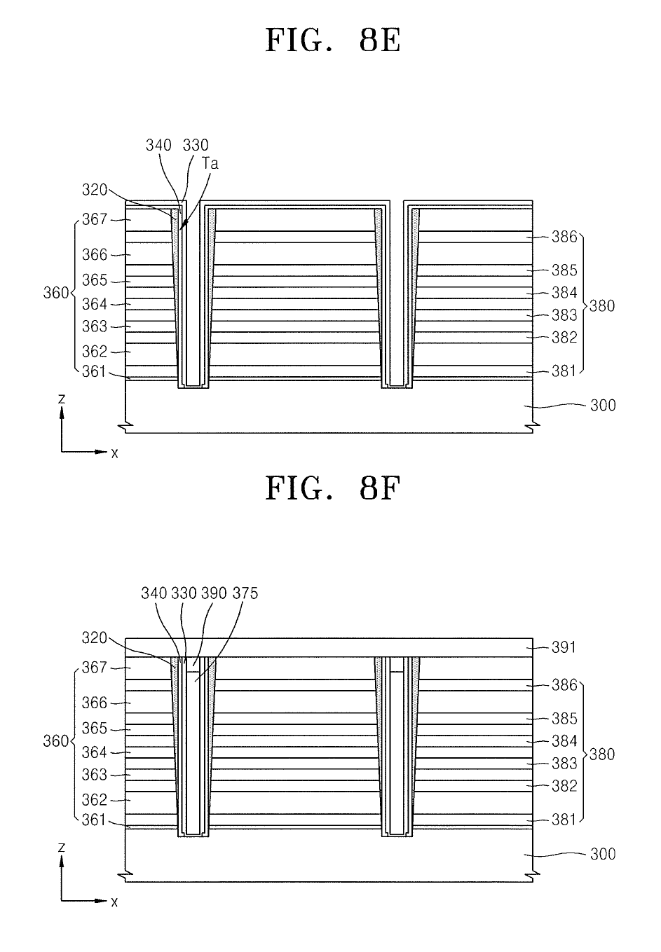

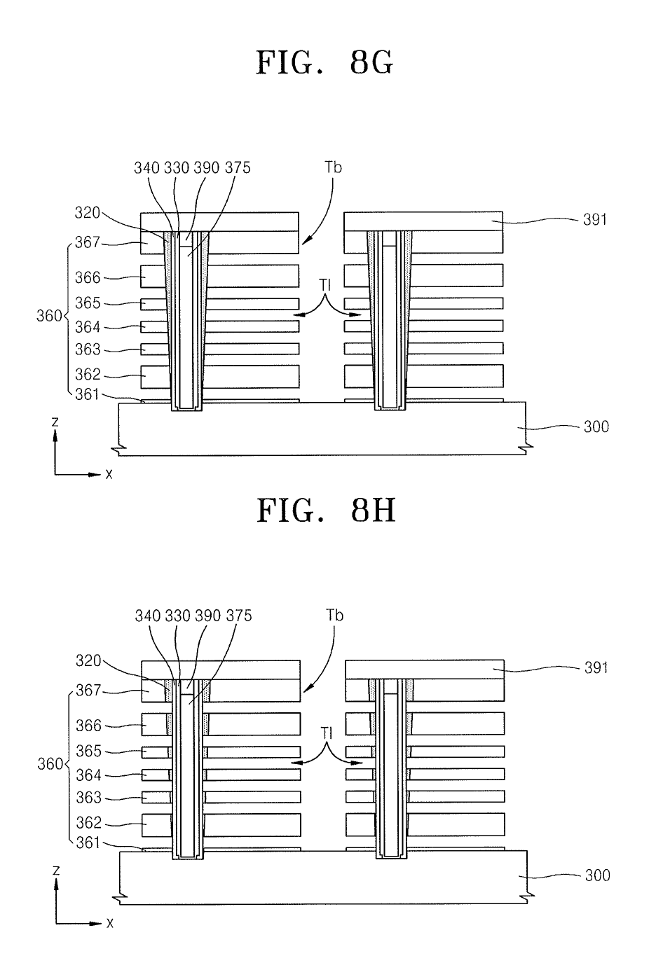

FIGS. 8A through 8I illustrate cross-sectional views of a method of manufacturing the non-volatile memory device 3000 of FIG. 7, according to another exemplary embodiment. Here, the cross-sectional views are taken along the y-axis direction of the perspective view of FIG. 7.

Referring to FIG. 8A, a plurality of interlayer sacrificial layers 380 (381 through 386) and the plurality of interlayer insulating layers 360 (361 through 367) may be alternately stacked on the substrate 300. As shown in FIG. 8A, the interlayer sacrificial layers 380 and the interlayer insulating layers 360 may be alternately stacked on the substrate 300 starting from the first interlayer insulating layer 361. Thicknesses of the interlayer insulating layers 360 may not be the same. The lowermost first interlayer insulating layer 361 of the interlayer insulating layers 360 may be formed thinner, and the second and sixth interlayer insulating layers 362 and 366 may be formed thicker.

The interlayer sacrificial layers 380 may be formed of a material which is etched by having an etching selectivity with respect to the interlayer insulating layers 360. In other words, the interlayer sacrificial layers 380 may be formed of a material that is etched while minimizing etching of the interlayer insulating layers 360 in a process of etching the interlayer sacrificial layers 380. The interlayer insulating layers 360 may be, e.g., at least one of silicon oxide layers and silicon nitride layers. The interlayer sacrificial layers 380 may be, e.g., one selected from silicon layers, silicon oxide layers, silicon carbide layers, and silicon nitride layers which are different from the material for the interlayer insulating layers 360.

The thicknesses of the interlayer insulating layers 360 and the interlayer sacrificial layers 380 may be variously modified. The number of layers constituting the interlayer insulating layers 360 and the number of layers constituting the interlayer sacrificial layers 380 may be variously modified. The number of interlayer insulating layers 360 and the number of interlayer sacrificial layers 380 may be variously modified.

Referring to FIG. 8B, first openings Ta may be formed to penetrate the stacked structure including the interlayer insulating layers 360 and the interlayer sacrificial layers 380 alternately stacked therein. The first openings Ta may be holes having depths in a z-axis direction. The first openings Ta may be isolation regions that are spaced apart from one another in an x-axis direction and a y-axis direction (refer to FIG. 7).

A process of forming the first openings Ta may includes forming predetermined mask patterns that define positions of the first openings Ta on the stacked structure of interlayer insulating layers 360 and the interlayer sacrificial layers 380, and alternately anisotropically etching the interlayer insulating layers 360 and the interlayer sacrificial layers 380 using the predetermined mask patterns as etch masks. The aspect ratios of the first openings Ta may be high. As the sidewalls of the first openings Ta get close to an upper surface of the substrate 300, widths of the first openings Ta may decrease, e.g., such that sidewalls of the first openings Ta may not be completely perpendicular to the upper surface of the substrate 300. As shown in FIG. 8B, the first openings Ta may expose parts, e.g., an upper surface, of the substrate 300.

Referring to FIG. 8C, the sidewall insulating layers 320 may be formed on the sidewalls of the first openings Ta. The sidewall insulating layers 320 have first thicknesses T1 at upper parts of the first openings Ta and may have thicknesses that are thinner toward the substrate 300. For example, the sidewall insulating layers 320 may have second thicknesses T2 thinner than the first thicknesses T1 at heights at which the third interlayer sacrificial layers 383 are formed. The sidewall insulating layers 320 may not be formed at lower parts of the first openings Ta. According to an exemplary embodiment, the sidewall insulating layers 320 may be formed to thicknesses thinner than the first thicknesses T1 at the lower surfaces of the first openings Ta.

The sidewall insulating layers 320 may include an insulating material. The sidewall insulating layers 320 may be formed of a material having a high step coverage characteristic and, e.g., a removal process may be performed to vary thicknesses in each of the sidewall insulating layers 320. Alternatively, the sidewall insulating layers 320 may be deposited to non-uniform thicknesses in the first openings Ta using a material having a low step coverage characteristic to have different thicknesses from entrances of the first openings Ta toward the substrate 100.

Referring to FIG. 8D, the gate dielectric layers 340 and pre-channel regions 330a may be formed to cover, e.g., uniformly cover, inner walls and lower surfaces of the first openings Ta. For example, the gate dielectric layers 340 may include at least continuous one layer that uniformly covers each sidewall insulating layers 320 and the lower surface of the first openings Ta. The gate dielectric layers 340 may be formed on, e.g., directly, on the sidewall insulating layers 320 and the lower surfaces of the first openings Ta.

The gate dielectric layers 340 may include, e.g., blocking insulating layers 346, charge storage layers 344, and tunneling insulating layers 342. The blocking insulating layers 346, the charge storage layers 344, and the tunneling insulating layers 342 may be sequentially stacked in the first openings TA in the above order. The blocking insulating layers 346, the charge storage layers 344, and the tunneling insulating layers 342 may be formed using, e.g., an ALD process, a CVD process, or a PVD process.

The pre-channel regions 330a may be formed using, e.g., an ALD process or a CVD process. The pre-channel regions 330a may be formed on, e.g., directly on, the gate dielectric layers 340. The pre-channel regions 330a may be formed to predetermined thicknesses, e.g., to thicknesses corresponding to half or less of thicknesses of the channel regions 330 of FIG. 8E.

Referring to FIG. 8E, parts of the gate dielectric layers 340 and the pre-channel regions 330a on lower surfaces of the first openings Ta may be etched to expose the substrate 300. The etch process may include a process of anisotropically etching the pre-channel regions 330a and etching the gate dielectric layers 340 using, e.g., the pre-channel regions 330a that have spacer shapes of which lower surfaces have been etched. Although not shown in FIG. 8E, as an over-etch result of the anisotropic etch process, parts of the substrate 300 exposed through the first openings Ta may be additionally recessed to predetermined depths.

Alternatively, the anisotropic etch process may be performed after the gate dielectric layers 340 are formed and before the pre-channel regions 330a are formed. In this case, the pre-channel regions 330a may contact the substrate 300. Further, a deposition of a channel material in addition to the pre-channel regions 330a, which will be described below, may be omitted.

The channel material may be deposited to uniformly cover the inner walls and the lower surfaces of the first openings Ta, thereby forming the channel regions 330 along with the pre-channel regions 330a. The channel material may be the same material as that of which the pre-channel regions 330a are formed, e.g., may include a semiconductor material such as polysilicon or single crystal silicon. The channel regions 330 may be coupled with to, e.g., directly contact, the substrate 300 so that the channel regions 330 may be electrically connected to the substrate 300.

Referring to FIG. 8F, the buried insulating layers 375 may be buried into the first openings Ta. A planarization process, e.g., a chemical mechanical polishing (CMP) process or an etch-back process, may be performed until the uppermost seventh interlayer layer insulating layers 367 are exposed. The planarization process may be performed to remove unnecessary semiconductor and insulating materials covering the uppermost seventh interlayer insulating layers 367.

Parts of upper parts of the buried insulating layers 375 may be removed using an etching process or the like. Thereafter, a conductive material may be deposited to form the conductive layers 390 in the removed positions of the buried insulating layers 375. Another planarization process may be performed to form the conductive layers 390 that may be disposed on the upper parts of the buried insulating layers 375 and that may be connected to the channel regions 330. An etch-stop layer 391 may be formed on the seventh insulating layers 367.

Referring to FIG. 8G, the second openings Tb may be formed to expose the substrate 300. The second openings Tb may extend in the y-axis direction (refer to FIG. 7). The process of forming the second openings Tb may include forming etch masks that define the second openings Tb, and anisotropically etching the interlayer insulating layers 360 and the interlayer sacrificial layers 380 underneath the etch mask until parts of the upper surface of the substrate 300 are exposed.

Parts of the interlayer sacrificial layers 380 exposed through the second openings Tb may be selectively removed (refer to FIG. 8). Due to the removal of the parts of the plurality of interlayer sacrificial layers 380, the plurality of side openings T1 may be formed among the plurality of interlayer insulating layers 360 to be connected to the second openings Tb and to be horizontal to the substrate 300. Parts of sidewalls of the sidewall insulating layers 320 and the channel regions 330 may be exposed through the side openings T1.

The process of forming the side openings T1 may include horizontally etching the interlayer sacrificial layers 380 using an etch recipe having etch selectivity with respect to the interlayer insulating layers 360. For example, if the interlayer sacrificial layers 380 are silicon nitride layers, and the interlayer insulating layers 360 may be silicon oxide layers. The horizontal etch process may be performed using, e.g., an etchant including a phosphoric acid. The etch process may be an isotropic etch process including, e.g., a wet etch or chemical dry etc (CDE).

Referring to FIG. 8H, the parts of the sidewall insulating layers 320 exposed through the side openings T1 may be removed. The removal of the exposed parts of the sidewall insulating layers 320 may be performed using a wet etch process. If the sidewall insulating layers 320 are formed of a material having an etch selectivity with respect to the interlayer insulating layers 360 and the channel regions 330, the exposed parts of the sidewall insulating layers 320 may be removed using the etching selectivity. Alternatively, if the sidewall insulating layers 320 do not have an etching selectivity with respect to the interlayer insulating layers 360 or have a low etching selectivity with respect to the interlayer insulating layers 360, an etch time may be controlled to minimize consumption of the interlayer insulating layers 360. For example, the etch time may be controlled based on and/or due to the relatively thinner thicknesses of the sidewall insulating layers 320 than side thicknesses of the interlayer insulating layers 360.

Referring to FIG. 8I, the second openings Tb and the side openings T1 of FIG. 8H may be filled with a conductive material. Therefore, the conductive material may be fully filled and uniformly deposited between the adjacent channel regions 130 through the second openings Tb. According to an exemplary embodiment, the sidewall insulating layers 320 may be formed to secure a length between the adjacent channel regions 330.

The conductive material may be etched to form the third openings Tc, which may have substantially the same widths and positions as the second openings Tb. The substrate 300 may be exposed through the third openings Tc. Therefore, the plurality of gate electrodes 350 (351 through 356) may be formed to enclose the channel regions 330.

Impurities may be injected into the substrate 300 through the third openings Tc to form the impurity regions 305. The impurity regions 305 may be adjacent to parts of the upper surface of the substrate 300 and may extend in the y-axis direction (refer to FIG. 7). The impurities regions 305 may be heavily-doped impurity regions that are formed by injecting, e.g., N+ type impurities. The process of forming the impurity regions 305 may not performed in the current process stage but may be performed in a previous or subsequent process stage.

A similar process as that of the method of manufacturing the non-volatile memory device 1000 of the previous embodiment described above with reference to FIG. 4K may be performed to complete the non-volatile memory device 3000 of FIG. 7.

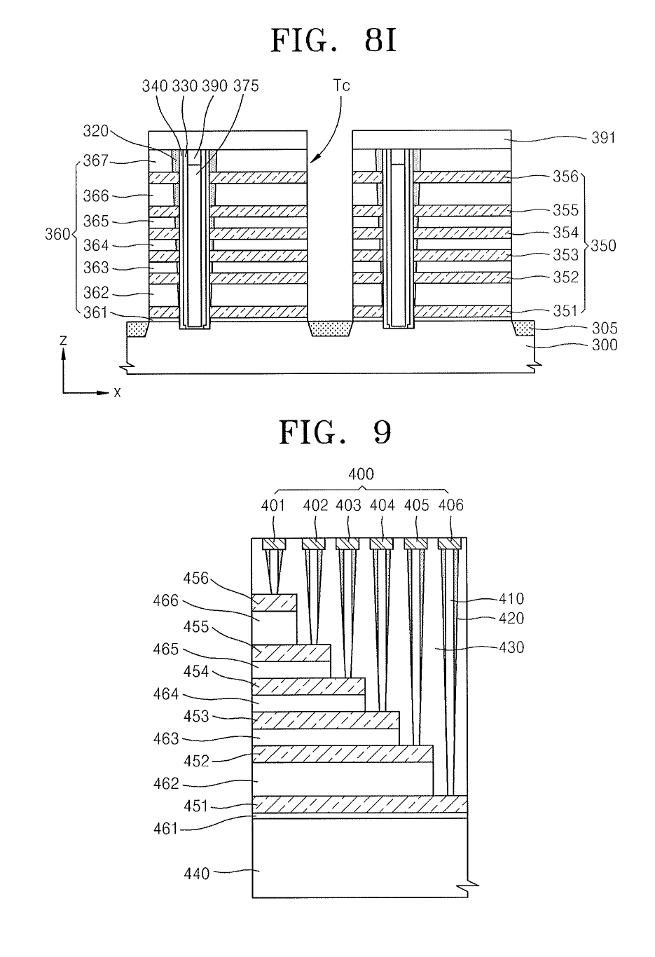

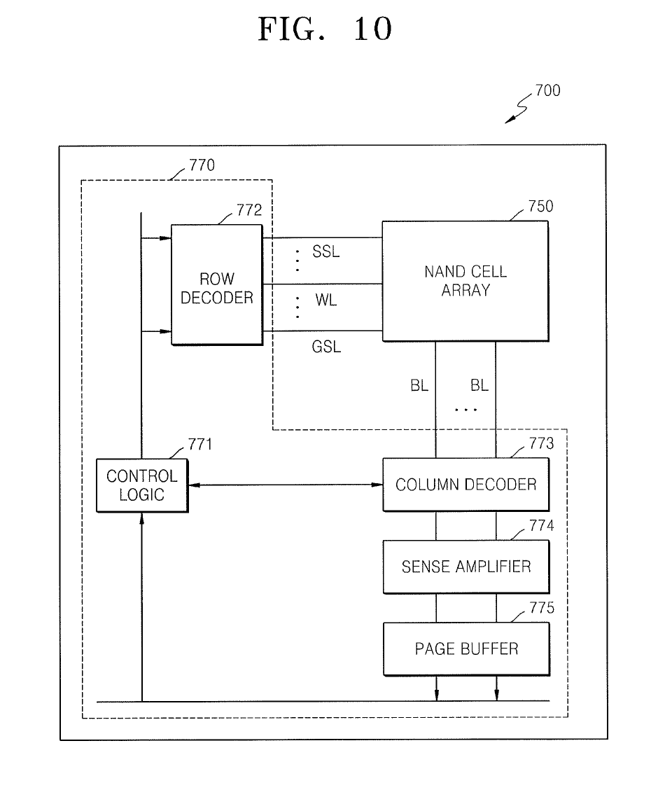

FIG. 9 illustrates a cross-sectional view of a connection region of a non-volatile memory device, according to an exemplary embodiment.

Referring to FIG. 9, wordlines 452, 453, 454, and 455 and selection lines 451 and 456 in the connection region may be connected to connection lines 400 (401 through 406) through contact plugs 410 on a substrate 440. Contact insulating layers 420 may be disposed in the contact plugs 410. The wordlines 452, 453, 454, and 455 may be connected to the gate electrodes 352, 353, 354, and 354, respectively, of the memory cells of FIG. 7 and thus may extend in the y-axis direction. The selection lines 451 and 456 may be connected to the gate electrodes 351 and 356 of the SSTs and the GSTs of FIG. 7 and thus may extend in the y-axis direction. The connection lines 400 may correspond to wiring structures that connect the wordlines 452, 453, 454, and 455 and the selection lines 451 and 456 to driving circuits of a peripheral circuit region (not shown).

The contact plugs 410 may be connected to the wordlines 452, 453, 454, and 455 and the selection lines 451 and 456 through connection region insulating layers 430. Similarly to the previous embodiments, contact holes (not shown) may be formed in the connection region insulating layers 430, and a material for contact insulating layers 420 may be deposited. The contact insulating layers 420 may be similar to the sidewall insulating layers 120, 220, and 320 discussed above. For example, the insulating layers 420 may have different thicknesses according to distances from a conductor (a corresponding one of wordlines 452, 453, 454, and 455 and the selection lines 451 and 456). For example, as a distance from the corresponding conductor includes, a thickness of the insulating layers 420 may increase. A conductive material may be deposited in the contact holes to complete the contact plugs 410.

As shown in FIG. 9, in the connection region, the contact plugs 410 may be arranged be adjacent to one another. Like the contact plug 410 connected to the lowermost selection line 451, a plurality of deep contact plugs may be formed. Therefore, if the contact plugs 410 are formed according to a contact plug forming method according to an exemplary embodiment, though the contact plugs 410 may have inclined sides, the contact plugs 410 may be connected to the wordlines 452, 453, 454, and 455 and the selection lines 451 and 456 without, e.g., substantial connection defects at lower parts of the connection regions and may be stably connected to the connection lines 400 at an upper part of the connection region.

FIG. 10 illustrates a schematic block diagram of a non-volatile memory device 700, according to an exemplary embodiment.

Referring to FIG. 10, the non-volatile memory device 700 may include a NAND cell array 750 and a core circuit unit 770 that are connected to each other. For example, the NAND cell array 750 may be included in one of the non-volatile memory devices 1000, 2000, and 3000 described with reference to FIGS. 3, 5, and 7 or 9. The core circuit unit 770 may include, e.g., a control logic 771, a row decoder 772, a column decoder 773, a sense amplifier 774, and a page buffer 775.

The control logic 771 may communicate with the row decoder 772, the column decoder 773, and the page buffer 775. The row decoder 772 may communicate with the NAND cell array 750 through a plurality of string selection lines SSL, a plurality of wordlines WL, and a plurality of ground selection lines GSL. The column decoder 773 may communicate with the NAND cell array 750 through a plurality of bitlines BL. When the NAND cell array 750 outputs a signal, the sense amplifier 774 may be connected to the column decoder 773. When the NAND cell array 750 receives a signal, the sense amplifier 774 may not be connected to the column decoder 773.

For example, the control logic 771 may transmit a row address signal to the row decoder 772, and the row decoder 772 may decode the row address signal and transmit the row address signal to the NAND cell array 750 through the string selection lines SSL, the wordlines WL, and the ground selection lines GSL. NAND. The control logic 771 may transmits a column address signal to the column decoder 773 or the page buffer 775. The column decoder 773 may decode the column address signal and transmit the column address signal to the NAND cell array 750 through the bitlines BL. The signal output from the NAND cell array 750 may be transmitted to the sense amplifier 774 through the column decoder 773. The sense amplifier 774 may amplify the signal and transmit the amplified signal to the control logic 771 through the page buffer 775.

FIG. 11 illustrates a schematic block diagram of a memory card 800, according to an exemplary embodiment.

Referring to FIG. 11, the memory card 800 may include a housing 830 having therein a controller 810 and a memory 820. The controller 810 and the memory 820 may exchange an electrical signal with each other. For example, the memory 820 and the controller 810 may exchange data with each other according to a command of the controller 810. Thus, the memory card 800 may store data in the memory 820 or output the data from the memory 820 to the outside.

For example, the memory 820 may include one of the non-volatile memory devices 1000, 2000, and 3000 described with reference to FIGS. 3, 5, and 7 or 9. The memory card 800 may be used as a data storage medium of various types of portable devices. For example, the memory card 800 may include a multimedia card (MMC) or a secure digital card (SDC).

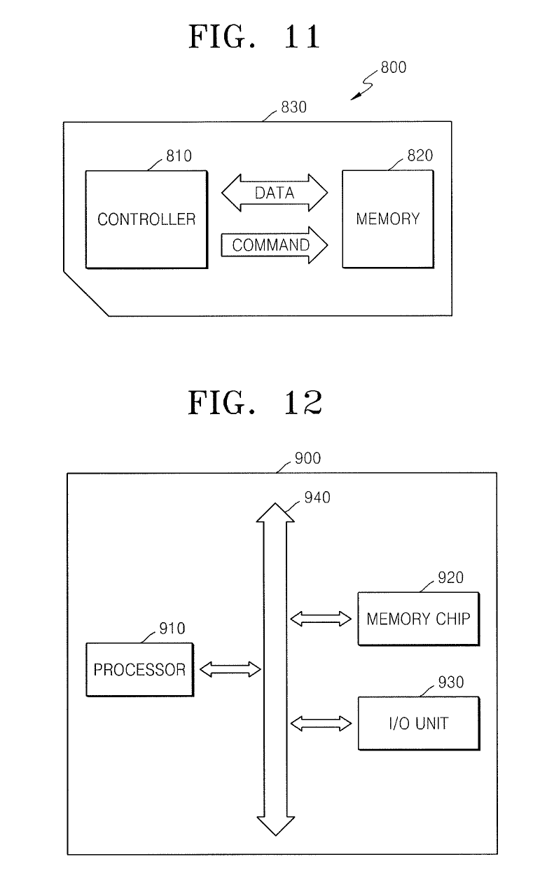

FIG. 12 illustrates a block diagram of an electronic system 900, according to an exemplary embodiment.

Referring to FIG. 12, the electronic system 900 may include a processor 910, and an input and/or output (I/O) unit 930, and a memory chip 920 that communicates data with one another through a bus 940. The processor 910 may execute programs and control the electronic system 900. The I/O unit 930 may be used to input data into and/or output data from the electronic system 900. The electronic system 900 may be connected to an external device, e.g., a personal computer or a network, through the I/O unit 930 and thus may exchange data with an external device. The memory chip 920 may store codes and data for an operation of the processor 910. For example, the memory chip 920 may include one of the non-volatile memory devices 1000, 2000, and 3000 described with reference to FIGS. 3, 5, and 7 or 9.

The electronic system 900 may constitute various types of electronic control devices using the memory chip 920, e.g., may be used in a mobile phone, an MP3 player, a navigation system, a solid state disk (SSD), household appliances, or the like.

While exemplary embodiments have been particularly shown and described, it will be understood that various changes in form and details may be made therein without departing from the spirit and scope of the following claims.

Embodiments may relate to a method of manufacturing a non-volatile memory device that has high integration and improved reliability and to a method of manufacturing contact plugs of a semiconductor memory device which has high integration and improved reliability. Embodiments may also relate to a contact plug of a semiconductor device that has high integration and improved reliability. Further, embodiments may relate to a non-volatile memory device having a vertical transistor structure, e.g., instead of a planar transistor structure, so as to have high integration and improved reliability.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a non-volatile memory device, the method comprising:
alternately stacking interlayer sacrificial layers and interlayer insulating layers on a substrate;
forming first openings exposing the substrate, the first openings penetrating the interlayer sacrificial layers and the interlayer insulating layers;
forming sidewall insulating layers on sidewalls of the first openings, the sidewall insulating layers having different thicknesses according to distances from the substrate; and
forming channel regions on the sidewall insulating layers.

2. The method as claimed in claim 1, wherein the thicknesses of the sidewall insulating layers decrease from upper parts of the first openings toward lower parts of the first openings.

3. The method as claimed in claim 2, wherein forming the sidewall insulating layers includes depositing an insulating material having a step coverage characteristic such that the insulating material is deposited thicker on the upper parts of the first openings than on the lower parts of the first openings.

4. The method as claimed in claim 1, wherein the sidewall insulating layers are formed above predetermined heights from the substrate.

5. The method as claimed in claim 1, wherein, prior to forming the channel regions, the sidewall insulating layers formed at lower surfaces of the first openings are removed.

6. The method as claimed in claim 5, wherein, when the sidewall insulating layers formed at the lower surfaces of the first openings are removed, portions of the sidewall insulating layers formed on the sidewalls of the first openings are simultaneously removed.

7. The method as claimed in claim 1, further comprising:
before forming the sidewall insulating layers, forming opening sacrificial layers in the first openings, the opening sacrificial layers having second heights that are lower than first heights of the first openings; and
after forming the sidewall insulating layers, removing the opening sacrificial layers.

8. The method as claimed in claim 7, wherein the sidewall insulating layers are formed above the second heights.

9. The method as claimed in claim 1, further comprising, after forming the channel regions,
forming second openings between ones of the channel regions, the second openings exposing the substrate and penetrating the interlayer sacrificial layers and the interlayer insulating layers;
removing parts of the interlayer sacrificial layers exposed through the second openings to form side openings, the side openings extending from the second openings and exposing parts of the channel regions and the sidewall insulating layers;
forming gate dielectric layers in the side openings; and
forming gate electrodes on the gate dielectric layers to fill the side openings, each gate electrode being one of a memory cell transistor electrode and a selection transistor electrode.

10. The method as claimed in claim 9, further comprising, before forming the gate dielectric layers, removing parts of the sidewall insulating layers exposed through the side openings.

11. The method as claimed in claim 9, wherein the channel regions are formed adjacent to one another in a first direction corresponding to an extending direction of the gate electrodes, and the channel regions are arrayed in zigzag forms.

12. The method as claimed in claim 9, further comprising:
providing a cell array region having memory cell transistors arranged therein, a peripheral circuit region having driving circuits arranged therein, and a connection region connecting the cell array region and the peripheral circuit region to each other; and
forming contact plugs in wordlines and selection lines to connect the driving circuits to the wordlines and the selection lines that are connected to the gate electrodes arrayed at same heights from the substrate, in the connection region.

13. The method as claimed in claim 12, wherein the formation of the contact plugs includes:
forming contact holes that penetrate connection region insulating layers, the contact holes being connected to the substrate,
forming contact insulating layers on sidewalls of the contact holes, and
forming conductive layers on the contact insulating layers to fill the contact holes.

14. A method of manufacturing contact plugs of a semiconductor device, the method comprising:
forming contact holes in an insulating material on conductors, each of the contact holes being connected to one of the conductors;
forming sidewall insulating layers on sidewalls of the contact holes, the sidewall insulating layers having different thicknesses according to distances from the conductors; and
forming conductive layers on the sidewall insulating layers to fill the contact holes.

15. The method as claimed in claim 14, wherein the thicknesses of the sidewall insulating layers decrease from upper parts of the contact holes toward lower parts of the contact holes.

16. A method of manufacturing a semiconductor device, the method comprising:
forming a stacked structure on a substrate, the stacked structure including a plurality of layers;
forming first openings in the stacked structure, the first openings including upper portions having greater widths than lower portions thereof, and each of the first openings exposing one of the plurality of layers or the substrate;
forming sidewall insulating layers on sidewalls of the first openings, the sidewall insulating layers being excluded adjacent to lower surfaces of the first openings such that portions of the sidewalls of the first openings and the lower surfaces of the first openings are exposed, and the sidewall insulating layers having different thicknesses according to distances from the lower surfaces of the first openings; and
forming at least one layer on the sidewall insulating layers in the first openings.

17. The method as claimed in claim 16, wherein:
forming the sidewall insulating layers includes deposing an insulating layer and removing portions of the insulating layer to form the sidewall insulating layers, and
removing portions of the insulating layer includes reducing a thickness of the insulating layer on the sidewalls of the first openings.

18. The method as claimed in claim 16, wherein forming the at least one layer on the sidewall insulating layers in the first openings includes forming channel regions directly on the sidewall insulating layers and forming a buried insulating layer directly on the channel regions, the method further comprising:
forming second openings in the stacked structure, the stacked structure including interlayer sacrificial layers and interlayer insulating layers alternately stacked therein;
removing the interlayer sacrificial layers through the second openings to form third openings, portions of the sidewall insulating layers being exposed through ones of the third openings and portions of the channel regions being exposed through others of third openings; and
removing the portions of the sidewall insulating layers exposed through the ones of the third openings such that other portions of the channel regions are exposed through the ones of the third openings.

19. The method as claimed in claim 18, further comprising:
forming gate dielectric layers directly on the portions of the channel regions exposed through the others of the third openings and directly on the other portions of the channel regions exposed through the ones of the third openings; and
forming conductive layers in the third openings directly on the gate dielectric layers.

20. The method as claimed in claim 18, further comprising forming conductive layers directly on the portions of the channel regions exposed through the others of the third openings and directly on the other portions of the channel regions exposed through the ones of the third openings.
